(19) United States
(12) Patent Application Publication
(10) Pub. No.: US 2025/0300357 A1
(43) Pub. Date: Sep. 25, 2025

(54) Antenna device and an automated test equipment comprising an orthomode transducer

(71) Applicants: José Moreira, Stuttgart (DE); Advantest Corporation, Tokyo (JP)

(72) Inventors: José MOREIRA, Stuttgart (DE); Sergey CHURKIN, Brentwood, CA (US); Maxim MURAVYEV, Brentwood, CA (US); Nikita BULYGIN, Brentwood, CA (US); Andrey MOZHAROVSKIY, Brentwood, CA (US); Olga ZHURAVLEVA, Brentwood, CA (US)

(21) Appl. No.: 19/229,499

(22) Filed: Jun. 5, 2025

Related U.S. Application Data
(63) Continuation of application No. PCT/EP2022/087140, filed on Dec. 20, 2022.

(51) Int. Cl. H01Q 13/06; G01R 31/28; H01Q 1/42

(52) U.S. Cl. CPC H01Q 13/06; G01R 31/2834; H01Q 1/42

(57) ABSTRACT

The invention relates to an antenna device comprising a quad-ridged waveguide, an open end of which is configured to act as a radiating aperture, and an orthomode transducer, OMT, configured to couple the quad-ridged waveguide to two feed structures.

### CROSS-REFERENCE TO RELATED APPLICATIONS

This application is a continuation of copending International Application No. PCT/EP2022/087140, filed Dec. 20, 2022, which is incorporated herein by reference in its entirety,

Embodiments according to the invention relate to an antenna device and an automated test equipment, in particular comprising a quad-ridged waveguide coupled to feed structures.

Furthermore, embodiments according to the invention relate to a single aperture wideband dual polarized waveguide antenna for an over-the-air socket.

Embodiments according to the invention are related to antennas transmitting or receiving electromagnetic waves of different spatial modes or polarizations.

### BACKGROUND OF THE INVENTION

Increasingly higher frequencies are used for modern devices such as mobile phones. For example, 5G NR (new radio) technology uses two frequency ranges, wherein a second frequency range FR2 may employ a bandwidth of, for example, 24 to 53 GHz, which spans a bandwidth of over an octave.

Testing such devices may, for example, make use of a plurality of antenna devices that cover the entire bandwidth as well as multiple polarizations of electromagnetic fields. Alternatively, in some cases antenna devices are used that have poor performance at at least one end of the bandwidth to be tested. Furthermore, it has been recognized that conventional antenna devices with improved performance (e.g. quad-ridged horn antennas) may suffer from difficulties and costs in manufacturing.

Therefore, there is a need for an antenna device that improves a compromise between bandwidth performance, multi-polarization reception, and manufacturing costs.

### SUMMARY

According to an embodiment, an antenna device may have: a quad-ridged waveguide, an open end of which is configured to act as a radiating aperture; and an orthomode transducer, OMT, configured to couple the quad-ridged waveguide to two feed structures.

Another embodiment may have an automated test equipment, wherein the automated test equipment comprises an inventive antenna device, wherein the automated test equipment is configured to test a device under test using the antenna device.

Another embodiment may have an automated test equipment, wherein the automated test equipment comprises a device under test socket and one or more high frequency connectors, wherein the one or more high frequency connectors are arranged beside the test socket.

An embodiment according to the invention is directed at an antenna device, comprising a quad-ridged waveguide, an open end of which is configured to act as a radiating aperture. The antenna device further comprises an orthomode transducer, OMT, configured to couple the quad-ridged waveguide to two feed structures.

It has been recognized that a quad-ridged waveguide is able to transmit (or receive) two different modes (i.e., electric field patterns), such as two different polarizations (wherein the wording “different polarizations” may, for example, mean orthogonal (H/V) modes). Since the quad-ridged waveguide is coupled to the OMT, two different modes of electric field can be coupled by the OMT into the quad-ridged waveguides. For example, a first mode (e.g. having a first orientation or a first polarization) in the quad-ridged waveguide may be excited by an input signal at a first port of the OMT (e.g. by a respective mode in the first feed structure), and a second mode (e.g. having a second orientation or a second polarization) in the quad-ridged waveguide may be excited by an input signal at a second port of the OMT (e.g. by a respective mode in the second feed structure). Since the OMT is also coupled to the two feed structures, the OMT enables coupling two different modes excited using the respective feed structures into the quad-ridged waveguide. With the quad-ridged waveguide having an open end as a radiating aperture, the two modes guided by the quad-ridged waveguide can be radiated (i.e., send/transmitted over the air). Therefore, the antenna device allows combining and transmission of two different polarization modes of electrical fields. The signal direction can also be reversed, e.g., a signal comprising an electrical field with two modes (e.g. orthogonal polarizations) can be received at the “radiating aperture” and guided by the quad-ridged waveguide to the OMT. In other words, the reciprocity principle may be applicable in embodiments according to the present invention (e.g. in the absence of nonreciprocal materials). The OMT may split the signal into its two modes that are subsequently “coupled into” the two feed structures (e.g., excite respective signals or modes in the two feed structures). The separation into two modes allows determining a polarization angle of electromagnetic radiation received at the radiating aperture or reception of two independent modes at the radiating aperture, which are split up by the OMT. Moreover, the antenna device is also capable of receiving or transmitting circularly or elliptically polarized radiation, e.g. using ancircuitry for providing phase shifts of input signals to the feed structures or for processing receive signals from the feed structures.

It should be noted that, in general, a polarization of an incoming wave can be different from H/V linear, e.g. inclined. Thus, in some embodiments, with this antenna device we can only guess on H or V or “mixed-polarization” wave. However, other embodiments may allow for a more precise determination of a polarization characteristic.

The antenna device therefor enables forwarding of more than one polarization mode, which can, for example, be used for more efficient testing of devices capable of multimode transmission and/or reception. The coupling between the quad-ridged waveguide, the OMT, and the feed structures can be implemented using a simple geometry that can be manufactured with low costs.

Moreover, it has been found that the usage of a quad-ridged waveguide provides for a very wide useable frequency range, which may, in some cases, exceed frequency-ratio of 2:1. In particular, the ridges provide for a wide frequency range in which there is only a single non-evanescent mode per polarization within the waveguide. Accordingly, a single antenna structure is sufficient to test wideband devices-under-test, taking into account two different polarizations or a circular or elliptic polarization.

The antenna device may, for example, be part of an over-the-air (OTA) socket measurement device. The antenna design has been found to be well-suited for OTA socket integration. A socket allows, for example, alignment between a device to be tested (also called device under test (DUT)) and the antenna device, optimizing communication therebetween. The antenna device may, for example, be a near-field testing antenna device. The antenna device may, for example, be a wideband antenna device. The antenna device may, for example, be a dual polarization single aperture antenna. The quad-ridged waveguide may, for example, be a rectangular (e.g., a square or oblong rectangle) quad-ridged waveguide. The radiating aperture may, for example, be configured to radiate electromagnetic waves of a first polarization and electromagnetic waves of a second polarization. For example, the first and second polarization may be oriented perpendicular relative to each other. The OMT may, for example, be a broadband orthomode transducer. The two feed structures may, for example, be configured to transmit (e.g. guide) electromagnetic waves. The two feed structures may, for example, comprise waveguides. The two feed structures may, for example, be or comprise two (or more) double-ridged waveguides. The quad-ridged (e.g., square) waveguide may, for example, be provided as a dual polarized interface of the OMT, forming a quad-ridged Boifot design. The antenna device may, for example, use a Boifot orthomode transducer (OMT) based concept to convert a single radiating aperture into two polarizations (e.g., horizontal and vertical) that are then routed to individual, for example, double-ridged waveguides for wide bandwidth operation.

According to an embodiment, the orthomode transducer is configured to couple a first feed structure with a first mode of the quad-ridged waveguide having a first orientation. The orthomode transducer may be configured to couple a second feed structure to a second mode of the quad-ridged waveguide having a second orientation.

The first feed structure may, for example, be coupled to two lateral ports of the orthomode transducer (e.g., the two lateral ports being arranged opposite each other at the OMT). The second feed structure may, for example, be a feed structure coupled to an axial port of the orthomode transducer. The first orientation may, for example, be at least essentially orthogonal (e.g. within a tolerance of +/−10 degrees) to the second orientation. Alternatively, the first and second orientations may, for example, be oriented at a different angle relative to each other (e.g., 30°, 45°, or 60°). The first mode and the second mode may, for example, excite radiation of waves having at least approximately orthogonal polarizations.

Accordingly, it is possible to have a good separation between different polarizations. For example, radiation of different (e.g. orthogonal) polarization may be excited using signals applied to different of the feed structures, and incoming radiation of different polarizations may excite separate signals at different of the feed structures, such that radiation of different polarizations is separately detectable.

According to an embodiment, lateral ports of the orthomode transducer are arranged in the same plane. For example, the lateral ports may be coupled to double-ridged waveguides and the ridges of the double-ridged waveguides may be arranged in a common plane. Such an arrangement reduces a phase difference that may occur with lateral ports that are arranged axially offset relative to each other. Moreover, fabrication costs can be kept reasonably small. For example, a number of layers that may be used for the fabrication may be kept small by having the lateral ports of the orthomode transducer in the same plane. Also, symmetry of the orthomode transducer may result in a particularly good separation of polarizations.

According to an embodiment, the antenna device forms a dual polarization single aperture antenna. For example, the antenna device may be a dual-polarized waveguide antenna, wherein two polarizations, e.g. vertical polarization and horizontal polarization, can be excited in a single quad-ridged waveguide aperture. The antenna device may be configured to transmit electromagnetic radiation from the single radiating aperture, which is formed by combining two modes of electromagnetic radiation received from the feed structures (and vice versa). This antenna structure comprises a small size while allowing for a good separation of polarizations. Moreover, fabrication costs can be kept reasonably small, e.g. when implementing the antenna using a small number of layers which are structured, e.g., using a milling process. For example, it has been found that the quad-ridged waveguide and the orthomode transducer can easily be fabricated using a layered structure comprising a small number of layers, wherein simple surface processing can be applied to shape the layers. Also, by using a single aperture only, a size of the antenna can be kept small, and good antenna characteristics can be achieved relatively close to the radiating aperture, since two polarizations are actually emitted from a single, common aperture.

According to an embodiment, at least one of the two feed structures comprises a double-ridged waveguide. Alternatively, at least one of the two feed structures comprises a single-ridged waveguide. At least one of the double-ridged waveguides may be configured to define a mode (and, to some degree also a polarization) excitable therein. Ridges increase the bandwidth of electromagnetic radiation excitable inside the waveguide (or, in other words, increase a frequency range in which only a single non-evanescent mode of a given polarization is excitable in the waveguide). Furthermore, ridges can, in some cases, define an advantageous direction for a polarization of electromagnetic waves. The double-ridged waveguides of the first and second feed structures may, for example, be configured such that polarizations of at least one double-ridged waveguide of the first feed structure and of at least one double-ridged waveguide of the second feed structure are disposed, e.g., perpendicular (or at least approximately perpendicular) to each other (e.g., when being feed to or by the OMT). For example, a first common plane spanned by ridges of a double-ridged waveguide of the first feed structure may be oriented perpendicular to a second common plane spanned by ridges of a double-ridged waveguide of the second feed structure (and, optionally, perpendicular to an extension direction of the double-ridged waveguide of the second feed structure).

According to an embodiment, the two feed structures extend between the orthomode transducer and respective blind-mating waveguide connections. The blind-mating waveguide connections may, for example, comprise self-aligning features. For example, the blind-mating waveguide connections may comprise at least one of a cone shaped opening or protrusion. At least one of the two feed structures may comprise one or more waveguides (e.g., one or more double-ridged waveguides) between the orthomode transducer and the respective blind-mating waveguide connections. The two feed structures may be configured to transmit an electromagnetic field between the orthomode transducer and respective blind-mating waveguide connections.

The blind-mating waveguide connections allow the antenna device to be easily and repeatedly (e.g., over a 100,000 times or a million times) coupled to a device for receiving and/or sending electromagnetic signals. For example, the antenna device may therefore be easily and repeatedly be coupled to a generator device and/or to an analysis device (e.g., of an automated test equipment) for generating and/or detecting signals to be emitted and/or received by the radiating aperture.

According to an embodiment, the antenna device comprises a layered structure, wherein the layered structure comprises: a first layer (or first housing portion) comprising the quad-ridged waveguide and, on an inner surface, a first portion (e.g. ridges, or a recesses with one or more ridges, wherein the recesses may, for example, form the waveguide's interior and/or a waveguide channel) of waveguide structures that extend between lateral ports of the orthomode transducer and a T-type waveguide joint. The layered structure may further comprise a second layer comprising, on a first side, a second portion (e.g. recesses with ridges) of the waveguide structures that extend between the lateral ports of the orthomode transducer and the T-type waveguide joint, and also comprising, on a second side, a first portion (e.g. a ridge, or a recess with one or more ridges) of a waveguide structure that extends from the T-type waveguide joint to a first external connection (and optionally also a first portion, e.g. a ridge or a recess with a ridge, of a waveguide structure that extends from the axial port of the orthomode transducer to a second external connection). The layered structure may further comprise a third layer comprising a second portion (e.g. a recess with a ridge) of the waveguide structure that extends from the T-type waveguide joint to the first external connection (e.g. a first blind-mating waveguide connection) and an optional (second) portion (e.g. a recess with a ridge) of the waveguide structure that extends from the axial port of the orthomode transducer to the second external connection (e.g. a second blind-mating waveguide connection).

The layered structure allows manufacturing inner hollow structures of the antenna device using simple metalworking techniques, such as milling and/or micromachining. Furthermore, the antenna device may be manufactured in metal. However, different fabrication techniques are also possible for a manufacturing of the surface-structured layers.

According to an aspect of the invention, the quad-ridged waveguide may be gradually or in discrete steps tapered in a direction from a first surface of the first layer towards a second (inner) surface of the first layer. The tapering allows for shorter antenna height and consequently reduces a size of the antenna device. In other words, while an “aperture” typically describes a lateral size, a stepped tapering may, for example, reduce an antenna height (e.g. an axial size).

According to an aspect of the invention, the T-type waveguide joint (or any other form of a combiner/splitter structure) can split a signal into two signal portions, which are shifted relative to each other (at least essentially, e.g. within a tolerance of +/− a tenth of a wavelength) by half a wavelength (or by approximately 180 degrees, e.g. within a tolerance of +/−10 degrees). The two signal portions can therefore be combined in phase, if the OMT also has a combiner/splitter structure (e.g., a OMT with a main port for the quad-ridged waveguide and two lateral ports for a first feed structure) that results in a half wavelength shift. The T-type waveguide joint therefore enables the use of an OMT with a combiner/splitter structure. Also, a highly symmetric structure can be obtained in this way.

According to an embodiment, the orthomode transducer comprises two lateral ports and one axial port. The axial port may, for example, be arranged opposite a main port coupling the quad-ridged structure to the OMT, e.g., such that a second feed structure coupled to the axial port (e.g., a double-ridged waveguide) is oriented at least essentially (e.g. with an angle difference of no more than 10 degrees) coaxially with the quad-ridged waveguide. The two lateral ports may, for example, be arranged at opposite sides of the OMT. The two lateral ports may be arranged such that (double-ridged) waveguides of the first feed (angle tolerance of no more than 10 degrees) structure coupled to the lateral ports extend at least essentially perpendicular (e.g. with an angle tolerance of no more than 10 degrees) to the quad-ridged waveguide.

Two lateral ports provide a larger symmetry compared to a single lateral port (in particular if the lateral ports, axial port, and main port are arranged in 90° angles relative to each other). A symmetric arrangement of the out-of-phase lateral ports and the axial port also improves cross-port isolation.

According to a further embodiment, a first lateral port of the orthomode transducer comprises a transition between the quad-ridged waveguide and a first double-ridged waveguide,

wherein a first ridge of the quad-ridged waveguide transitions into a first ridge of the first double-ridged waveguide (e.g. the first ridge of the quad-ridged waveguide lies in a same plane as the first ridge of the first double-ridged waveguide). A second lateral port of the orthomode transducer may comprise a transition between the quad-ridged waveguide and a second double-ridged waveguide, wherein a second ridge of the quad-ridged waveguide (which may be opposite to the first ridge of the quad-ridged waveguide) transitions into a first ridge of the second double-ridged waveguide (e.g. the second ridge of the quad-ridged waveguide lies in a same plane as the first ridge of the second double-ridged waveguide).

An axial port of the orthomode transducer may comprise a transition between the quad-ridged waveguide and a third double-ridged waveguide, wherein a third ridge of the quad-ridged waveguide may transition into a first ridge of the third double-ridged waveguide and a fourth ridge of the quad-ridged waveguide may extend into a second ridge of the third double-ridged waveguide.

The transitions between the ridges (e.g. gradient transitions of discrete steps transitions) improve coupling of modes between the feed structures and the quad-ridged waveguides. The transitions reduce discontinuity of structures within the antenna device, which improves return loss. Moreover, unwanted modes conversions are well-suppressed using such a concept.

For example, the first ridge of the quad-ridged waveguide, the second ridge of the quad-ridged waveguide, the first ridge of the first double-ridged waveguide and the first ridge of the second double-ridged waveguide may all lie within a same (first) plane. The third ridge of the quad-ridged waveguide, the fourth ridge of the quad-ridged waveguide, the first ridge of the third double-ridged waveguide and the second ridge of the third double-ridged waveguide may all lie within a same (second) plane, wherein, for example, the second plane is perpendicular (e.g. within a tolerance of +/−10 degrees) to the first plane. Such an arrangement improves discrimination of two modes of electromagnetic waves that are perpendicular (orthogonal) to each other.

According to an embodiment, the antenna device (e.g., an antenna structure) comprises a waveguide structure (e.g. the first double-ridged waveguide and the second double-ridged waveguide) connecting a first lateral port of the orthomode transducer and a second lateral port of the orthomode transducer with a combiner/splitter structure (e.g. a T-junction; e.g. an E-plane T-junction).

Using two lateral ports improves symmetry and therefore cross-port isolation. For example, unwanted modes conversion is well-suppressed. The combiner/splitter structure at least partially compensates a phase shift between the two signals combined at the two lateral ports.

For example, the waveguide structure and at least a part of the combiner/splitter structure may lie in a same layer of the antenna structure like the first lateral port and the second lateral port or may be arranged at a same transition between two layers of the antenna device like the first lateral port and the second lateral port. Such an arrangement in the same layer facilitates manufacturing and improves symmetry and, by extension, cross-port isolation.

According to an embodiment, the antenna device (e.g., the antenna structure) comprises a portion of the waveguide structure, which is coupled to the combiner/splitter structure (and which extends from the combiner/splitter to a first external connection), wherein the portion of the waveguide structure that extends from the axial port of the orthomode transducer to the second external connection (e.g. the second blind-mating waveguide connection) and the portion of the waveguide structure coupled to the combiner/splitter structure are arranged in a same (common) layer of the antenna device (e.g., the antenna structure) and/or are arranged at a same (common) transition between two layers of the antenna device.

With the portions of the waveguide structure being arranged in a same layer and/or same transition between two layers, both structures (which may be long hollow structures) can be manufactured using simple metalworking techniques, such as milling (e.g., using a CNC-milling center) and/or micromachining. However, other technologies for producing surface-structured layers may also be applied.

According to an embodiment, the antenna device is implemented in an antenna housing, wherein the antenna housing comprises at least two portions.

An antenna housing with two or more portions provides ease of assembling, maintenance and can be manufactured using simple metalworking techniques, such as milling and/or micromachining.

The antenna housing may be or may comprise a metal structure in which at least the quad-ridged waveguide, the orthomode transducer and the feed structures are formed. For example, the entire antenna device may be made from metal. The antenna housing may comprise or consist of a metal (or a metal alloy). At least two (e.g., two, three, four, five, or more) housing portions may comprise at least two structured metal layers attached to each other (e.g., by screws or a welded joint). The metal layers may, for example, be at least essentially congruent. The metal layers may, for example have a thickness in a range of 2 mm to 7 mm. The antenna housing may, for example, have a thickness between 10 to 15 mm.

According to an embodiment, the antenna housing comprises a first housing portion (e.g. a first layer) and a second housing portion (e.g. a second layer), wherein the quad-ridged waveguide is milled and/or micromachined in the first housing portion, wherein the first double-ridged waveguide and the second double-ridged waveguide are, at least partially (or, optionally, fully), milled and/or micromachined in the second housing portion, or are milled and/or micromachined in between the first housing portion and the second housing portion. The third double-ridged waveguide may, for example, be milled and/or micromachined in the second housing portion, wherein an inner surface of the first housing portion forms a part (e.g. a wall, e.g. a cap, e.g. a cover) of the first and second double-ridged waveguides.

Milling and micromachining are processes that are energy efficient (e.g., as no metal melting needed) and can be largely automated (e.g., using computer numerical control, CNC). Milling and/or micromachining hollow structures between two layers decreases limitations of such metal working techniques in regards to forming long hollow structures. However, different fabrication techniques may also be applied in some embodiments.

According to an embodiment, ridges of the third double-ridged waveguide are connected to (e.g. transition into) a (vertical) pair of (opposite) ridges of the quad-ridged waveguide via a ridge step. The ridge step may, for example, be formed in the second housing portion.

The ridge step can, for example, improve a smooth transformation of a polarization (e.g., vertical polarization) between the third double-ridged waveguide and the quad-ridged waveguide.

According to a further embodiment, the antenna housing comprises a first housing portion (e.g. a first layer), a second housing portion (e.g. a second layer) and a third housing portion (e.g. a third layer). The quad-ridged waveguide may be milled and/or micromachined in the first housing portion. The first double-ridged waveguide and the second double-ridged waveguide may be, at least partially (or, optionally, fully), milled and/or micromachined in the second housing portion, or are milled and/or micromachined at a transition between the first housing portion and the second housing portion. The third double-ridged waveguide may be milled and/or micromachined in the second housing portion, and a combiner/splitter structure (e.g. a T-junction; e.g. an E-plane T-junction) may be milled and/or micromachined in the second housing portion (and optionally may also include structures in the first housing portion). The second housing portion may form a part (e.g. a wall, e.g. a cap, e.g. a cover) of the first and second double-ridged waveguides.

The distribution of mechanical features amongst the three housing portions, as described above, arranges structures that form waveguide structures onto two housing portions, which simplifies the milling and/or micromachining process. Since waveguide structures are (for the most part) arranged between housing structures (or at a transition between housing structures, or in between housing structures), the waveguide structures can extend (e.g., meander steps) parallel to an extension direction of the layers. For example, a waveguide channel is formed inside/in between these housing structures. As a result, the waveguide structures do not have to extend perpendicular to the layers and the layers can be manufactured thinner, resulting in a more compact antenna device.

According to a further embodiment, the lateral ports are electromagnetically isolated (e.g. polarization-isolated) from the axial port. This means, for example, that the lateral ports have a small coupling (high electromagnetic isolation) from the axial port. For example, the lateral ports may have a coupling of less than −10 dB or of less than −20 dB or of less than −30 dB with the axial port.

An isolation of the axial and lateral ports reduces mixing of modes coupled in the first and second feed structures and consequently increases a signal quality.

The lateral ports may be isolated (e.g. polarization-isolated) from the axial port such that the lateral ports couple to an electromagnetic wave of a first polarization and such that the axial port couples to an electromagnetic wave of a second polarization, which may, for example, be orthogonal to the first polarization. An attenuation between the lateral ports and the axial port may, for example, be higher than 10 dB, or even higher than 20 dB, or even higher than 30 dB. Thus, signals with sufficiently clean polarization characteristic can be emitted by the antenna device, or a different polarization components (e.g. linear polarization components) of a received signal can be separated effectively.

According to an embodiment, the quad-ridged waveguide extends perpendicular to the radiating aperture. This allows for a simple manufacture, by using, e.g. milling, and provides good and predictable radiation characteristics.

A difference of the antenna beams directions of the two polarizations transmitted (or received) by the radiating aperture is therefore eliminated.

According to an embodiment, ridges of the quad-ridged waveguide extend up to the radiating aperture. The ridges may extend up to the radiating aperture in tapered or non-tapered (e.g. gradient) form.

With the ridges extending up to the radiating aperture, mode mixing inside the quad-ridged waveguide is reduced. Also, the tapered ridges improve antenna impedance matching, that, therefore, widens the operational bandwidth-similar to the quad-ridged horn antennas principle.

According to an embodiment, the quad-ridged waveguide comprises a constant (e.g. invariable) cross-section along its longitudinal extension (e.g. is non-tapered; e.g. comprises a cuboid shape with 4 ridges). The ridges of the quad-ridged waveguide may have a variable cross-section along the extension of the waveguide (e.g., due to tapering).

The variability of the ridges' cross-section (ridges' shapes) is tuned to provide wideband impedance matching of the antenna, whereas a constant cross-section of the waveguide (cuboid waveguide interior) may bring along a good producibility and good electrical characteristics.

According to an embodiment, the antenna device provides a wideband antenna operation (e.g., having a bandwidth over more than an octave, e.g. with a frequency ratio >2:1). The antenna device may, for example, provide a wideband antenna that operates in a range of 20 to 60 GHz, such as 24 to 53 GHz.

As a result, a single antenna device can cover a wide variety of applications, which reduces testing costs for a user and development and support costs for a manufacturer. Furthermore, the antenna device has an improved compatibility with broadband cellular network standards such as 5G (e.g., 5G NR) or higher. The antenna device may, for example, cover one or more frequency ranges of the 5G (e.g., 5G NR) standard such as the FR2 and/or FR1 frequency range.

According to an embodiment, the antenna device is (or is part of) an over-the-air (OTA) socket measurement device.

A socket allows fixing devices to be tested and therefore enables orienting a device's transmission/reception in a way that over-the-air transmission can be aimed at the radiating aperture, which improves reproducible and repeated testing.

According to an embodiment, the antenna device is a near-field testing antenna device.

The quad-ridged antenna allows close proximity (e.g., 1 cm) to a device to be tested. Therefore, the antenna device is suitable for near-field testing. This allows for small dimensions of the antenna device and of a test arrangement comprising the antenna device.

According to an embodiment, the antenna device comprises an electromagnetically permeable (e.g. radio transparent or electromagnetically transparent) cover, which covers at least a part of the antenna device (or of the antenna) and/or which covers at least a part of the waveguide.

For example, depending on the DUT size the cover can be bigger than the quad ridged waveguide or aperture. The objective of the cover is, for example, to be the device pusher into the electrical socket. In some embodiments, the objective of the cover is not to cover or protect the measurement antenna. It is, for example, made of metal, it does not need protections in some embodiments.

In other words, for example, it may be the objective (or the primary objective) of the cover to push the device and it is, in some cases, determined by the DUT size. In some embodiments, it is not an objective of the cover to cover the waveguide opening.

The cover allows mechanically touching and/or pushing a device to be tested (e.g., to push or hold the device to be tested in a socket and/or reduce distance for near-field testing) while reducing the risk of the device to be tested to touch a housing of the antenna device, and while still allowing transmission of electromagnetic waves between the antenna device and the device to be tested.

According to a further embodiment, the cover is configured to push a device under test into a device under test location (e.g. into a test socket) while allowing for a transit of electromagnetic radiation from the waveguide to the device under test or vice versa. Thus, testing can be accelerated, and an appropriate distance between the antenna aperture and the device under test can be achieved.

An embodiment according to the invention relates to an automated test equipment (ATE),

wherein the automated test equipment comprises an antenna device as described herein, wherein the automated test equipment is configured to test a device under test (e.g. a wireless device under test; e.g. an antenna-in package device under test) using the antenna device.

The automated test equipment according to this embodiment is based on the same considerations as an antenna device described above. Moreover, this disclosed embodiment may optionally be supplemented by any other features, functionalities and details disclosed herein in connection with the antenna device, both individually and taken in combination.

According to an embodiment, the automated test equipment comprises a device under test socket and one or more (e.g. blind mating) high frequency connectors (e.g. waveguide connectors) (e.g. for establishing a high frequency connection with the antenna device),

wherein the one or more high frequency connectors are arranged beside the test socket.

The socket and the arrangement of the high frequency connectors besides the socket allow simultaneous and simple establishment of a (wireless) connection (or coupling) of the antenna device to the test socket and of a connection to the connectors. Blind mating connectors enable a high success rate coupling process with low wear over numerous coupling procedures. Moreover, the coupling can be effected automatically, e.g. using a handler or a robot arm.

According to an embodiment, the high frequency connectors are blind mating waveguide connectors comprising double-ridged waveguides.

The double-ridged waveguide connectors provide an increased bandwidth. Furthermore, improved compatibility is provided if the feed structures also have double-ridged waveguide connectors.

According to an embodiment, the test socket and the one or more high frequency connectors are arranged such that one or more external connections of the antenna device mate with the one or more high frequency connectors and such that a cover of the antenna device pushes the device under test into the device under test socket when the one or more external connections of the antenna device mate with the one or more high frequency connectors.

An alignment of the external connections of the antenna device with the high frequency connectors is facilitated when the cover of the antenna device pushes the device under test into the device under test socket. Moreover, the blind mating high frequency connectors may well align the antenna device, such that the device under test is also properly pushed into its device-under-test socket by the antenna device. Thus, the blind mating connectors do not only establish a microwave connection, but at the same time serve as mechanical alignment elements.

The one or more external connections of the antenna device may comprise double-ridged waveguide connectors and the double-ridged waveguides of the high frequency connectors may be oriented and/or dimensioned such that when they mate with the external connections of the antenna device, the double-ridges of the one or more external connections and the high frequency connectors at least essentially transition along the connection of the corresponding double-ridged waveguides (e.g., due to an at least essentially congruent cross-section of the double-ridged waveguides). Such a transition between two double-ridged waveguides improves return loss. Also, a wideband operation of the antenna device in ensured by this design.

According to an embodiment, the cover of the antenna device is formed from a low dielectric constant material (e.g. a plastic pusher). The cover therefore has less dielectric loss. Moreover, the field distribution experiences little degradation from such a cover.

### BRIEF DESCRIPTION OF THE DRAWINGS

Embodiments of the present invention will be detailed subsequently referring to the appended drawings, in which:

FIG. 1 shows a schematic view of an embodiment of an antenna device comprising a quad-ridged waveguide;

FIG. 2A shows a perspective view of an embodiment of an antenna device in form of a quad ridge horn antenna design with a step-like ridges geometry;

FIG. 2B shows a perspective assembly view of the QHRA depicted in FIG. 2A;

FIG. 3A shows a cross-sectional view along a line A-A′ depicted in FIG. 2A;

FIG. 3B shows a graphic representation of an E-field pattern in the antenna structure of FIG. 2A;

FIG. 4A shows graphic representation of scattering parameters (S-parameters) and gain of a simulation of the QRHA depicted in FIGS. 2A to 3B;

FIG. 4B shows a three dimensional far-field (3d FF) pattern of a simulation of the QRHA depicted in FIGS. 2A to 3B;

FIG. 5A shows a graphic representation of a far-field radiation pattern in polar coordinates, in the elevation plane, comprising the first feed structure when the antenna is fed through the first feed structure (vertical port) at three different frequencies F₁=24.25 GHz, F₂=38.5 GHz, F₃=53 GHz;

FIG. 5B shows a graphic representation of a far-field radiation pattern in polar coordinates, in the azimuth plane, comprising the second feed structure when the antenna is fed through the second feed structure (horizontal port) at three different frequencies F₁=24.25GHz, F₂=38.5 GHz, F₃=53 GHz;

FIG. 6 shows a perspective view of an embodiment of an antenna device with a quad ridged horn antenna concept with double-ridged waveguide interfaces;

FIG. 7A shows a perspective view of a Boifot OMT design;

FIG. 7B shows a cutplane view of an OMT modification with stepped ridges;

FIG. 8A shows a 3D model of a two-piece OMT housing with vertical ridges;

FIG. 8B shows a drawing of the two-piece OMT housing of FIG. 8A;

FIG. 9 shows a perspective view of a further embodiment of the antenna device;

FIG. 10A shows a perspective view of an embodiment of the antenna device of FIG. 9, wherein solid structures are not (or barely) visible;

FIG. 10B shows a cross-sectional view of the antenna device of FIG. 10A through a plane B;

FIG. 10C shows a cross-sectional view of the antenna device of FIG. 10A through a plane C;

FIG. 10D shows a cross-sectional view of the antenna device of FIG. 10A through a plane D;

FIG. 10E shows a cross-sectional view of the antenna device of FIG. 10A through a plane E;

FIG. 11 shows a graphic representation of a simulated reflection coefficients (S₁₁, S₂₂) for horizontal and vertical polarizations (wherein it should be noted that the return loss RL is, by definition, a positive value, e.g. abs(S11));

FIG. 12A shows a simulation of an E-field pattern (instant vector pattern) for vertical polarization of a vertical cross section through the antenna device;

FIG. 12B shows a simulation of the E-field pattern (instant field distribution) for vertical polarization of a horizontal cross section through the antenna device;

FIG. 13A shows a simulation of an E-field pattern (instant vector pattern) for horizontal polarization of a horizontal cross section through the antenna device;

FIG. 13B shows a simulation of the E-field pattern (instant field distribution) for horizontal polarization of a vertical cross section through the antenna device;

FIG. 14A shows a perspective view of a further embodiment of the antenna device;

FIG. 14B shows a perspective view of the antenna device of FIG. 14A, providing a view of a lateral arm and an axial arm;

FIG. 15A shows a perspective view of the antenna device of FIG. 14A, providing a view of a first inner surface of a first housing portion;

FIG. 15B shows a perspective view of the antenna device of FIG. 14A, providing a view of a second inner surface of a second housing portion;

FIG. 16A shows a perspective view of a cross-section of the antenna device shown in FIG. 14A to 15B, wherein the cross section extends along a vertical plane (ZY);

FIG. 16B shows a perspective view of a cross-section similar to the one depicted in FIG. 16A, wherein the cross section is offset in a positive x-direction;

FIG. 17A shows a perspective view of a cross-section of the antenna device of FIG. 14A, wherein the cross section extends along a horizontal plane (ZX);

FIG. 17B shows perspective view of a cross-section similar to the one depicted in FIG. 17A, wherein the cross section is offset in a negative y-direction;

FIG. 18A shows a perspective view of a cross section of the antenna device of FIG. 14A, wherein the plane for the cross section is positioned at 7 mm along Z axis;

FIG. 18B shows a perspective view of a cross section of the antenna device of FIG. 14A, wherein the plane for the cross section is positioned at 5.5 mm along Z axis;

FIG. 18C shows a perspective view of a cross section of the antenna device of FIG. 14A, wherein the plane for the cross section is positioned at 3 mm along Z axis;

FIG. 18D shows a perspective view of a cross section of the antenna device of FIG. 14A, wherein the plane for the cross section is positioned at 2.5 mm along Z axis;

FIG. 18E shows a perspective view of a cross section of the antenna device of FIG. 14A, wherein the plane for the cross section is positioned at 1.5 mm along Z axis;

FIG. 18F shows a perspective view of a cross section of the antenna device of FIG. 14A, wherein the plane for the cross section is positioned at −0.5 mm;

FIG. 19A shows a first perspective view of a further embodiment of the antenna device;

FIG. 19B shows a second perspective view of the antenna device of FIG. 19A;

FIG. 20A shows a perspective view of a first surface of the first housing portion;

FIG. 20B shows a perspective view of a second surface of the first housing portion;

FIG. 21A shows a perspective view of a first surface of a second housing portion;

FIG. 21B shows a perspective view of a second surface of the second housing portion;

FIG. 22A shows a perspective view of a first surface of a third housing portion;

FIG. 22B shows a perspective view of a second surface of the third housing portion;

FIG. 23A shows a perspective view of a further embodiment of an antenna device;

FIG. 23B shows a frontal wireframe view of the antenna device of FIG. 23A;

FIG. 24A shows a perspective view of hollow structures inside the antenna device of FIG. 23A;

FIG. 24B shows a perspective view of the antenna device of FIG. 24A from essentially an opposite view point compared to FIG. 24A;

FIG. 25A shows an exploded view of the antenna device of FIG. 23A with a view of top surfaces of each of three housing portions;

FIG. 25B shows an exploded view of the antenna device of FIG. 23A with a view of bottom surfaces of each of the three housing portions;

FIG. 26A shows a graphic representation of a simulation for reflection coefficients (S₁₁, S₂₂) and gains of an antenna device such as the antenna device of FIG. 23A;

FIG. 26B shows a simulation for far-field patterns of a horizontal polarization at 24 GHz;

FIG. 26C shows a simulation for far-field patterns of a horizontal polarization at 53 GHz;

FIG. 26D shows a simulation for far-field patterns of a vertical polarization at 24 GHz;

FIG. 26E shows a simulation for far-field patterns of a vertical polarization at 53 GHz;

FIG. 27A shows a graphic representation of a simulation for a far-field radiation pattern in polar coordinates, for horizontal polarization at frequencies of F₁=24 GHz, F₂=37 GHz, F₃=53 GHz;

FIG. 27B shows a graphic representation of a simulation for a far-field radiation pattern in polar coordinates, for vertical polarization at frequencies of F₁=24 GHz, F₂=37 GHz, F₃=53 GHz;

FIG. 27C shows a graphic representation of a simulation for E-field components' (X, Y) magnitudes of a probe pair placed 11 mm above an antenna aperture;

FIG. 28 shows a perspective view of an embodiment of an automated test equipment with an antenna device without a cover;

FIG. 29 shows a perspective view of the embodiment of FIG. 28, wherein the antenna device further comprises a cover; and

FIG. 30 shows a perspective view of the antenna device of FIGS. 28, 29 mated to a test socket and high frequency connectors.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

In order to improve understanding of the present disclosure, terminology such as “feed” and “radiating” is used, indicating one exemplary signal direction, e.g., signals traveling from “feed” structures to a “radiating” quad-ridged waveguide. However, it is to be understood, that the antenna device disclosed herein also allows signal propagation in the opposite direction (e.g. from a radiating aperture of a quad-ridged waveguide to feed structures) (e.g. due to antenna or passive device reciprocity).

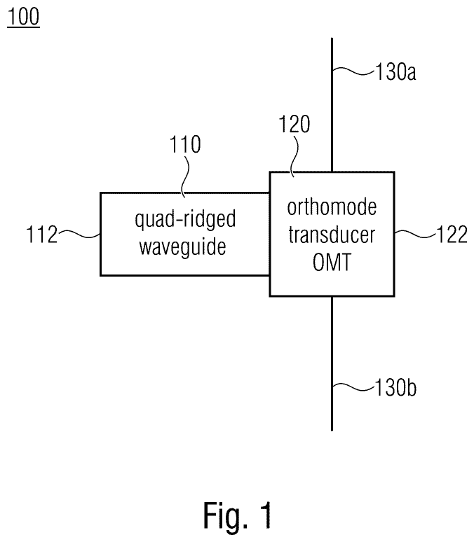

FIG. 1 shows a schematic view of an embodiment of the antenna device 100. It should be noted that the schematic view of FIG. 1 does not imply any specific geometry of the antenna device 100.

The antenna device 100 comprises a quad-ridged waveguide 110 with an open end that is configured to act as a radiating aperture 112. The antenna device 100 further comprises an orthomode transducer, OMT, 120 configured to couple the quad-ridged waveguide 110 to two feed structures 130a, 130b.

The quad-ridged waveguide 110 may, for example, have a rectangular (e.g., in the shape of a square or oblong rectangle) cross section. Alternatively, the quad-ridged waveguide may, for example, have a differently shaped cross-section, e.g., a circle, an oval, or a polygon. The quad-ridged waveguide 110 may comprise a ridge on each of its four inner surfaces (e.g., along a center line of the corresponding inner surface). The quad-ridged waveguide 110 may be configured to transmit (or guide) electromagnetic waves with at least a first and second mode. The first and second mode may be oriented at least essentially orthogonal relative to each other. The quad-ridged waveguide 110 may be configured to transmit (or guide) the two modes at least essentially independently. The quad-ridged waveguide 110 may have only a straight extension direction (e.g., without bending) between the radiating aperture 112 and the OMT 120.

The radiating aperture 112 may be configured to radiate electromagnetic waves of a first polarization and electromagnetic waves of a second polarization, i.e. based on the first and second mode (wherein, for example, a field distribution in the radiating aperture may be defined by the respective modes). The radiating aperture 112 may, for example, be formed at a flat end of the quad-ridged waveguide 110. The flat end of the quad-ridged waveguide 110 may, for example, be oriented perpendicular (or approximately perpendicular, e.g. within a tolerance of +/−10 degrees) to an extension direction of the quad-ridged waveguide 110, i.e. the quad-ridged waveguide 110 may extend (at least approximately) perpendicular to the radiating aperture 112. The ridges of the quad-ridged waveguide 110 may, for example, extend up to the radiating aperture 112. Alternatively, the ridges of the quad-ridged waveguide 110 may not reach the radiating aperture 112.

The two feed structures 130a, 130b may comprise a waveguide structure and a second waveguide structure. Alternatively or additionally, at least one of the first and second feed structure 130a, 130b may comprise at least one of a coaxial line and an endlauch waveguide adapter (e.g., for coupling a waveguide to a coaxial line and/or vice versa). At least one of the two feed structures 130a, 130b may comprise one or more waveguides. At least one of the two feed structures 130a, 130b may comprise two more waveguides coupled to the OMT 120. In the embodiment depicted in FIG. 1, each feed structure 130a, 130b comprises a single waveguide coupled to the OMT 120. The feed structures 130a, 130b (or waveguides thereof) may couple to the OMT 120 at a 90° angle or at a 180° angle (or any other angle such as 30°, 45°, 60°, 120°, or 180°).

The OMT 120 may comprise three (or more) ports coupled to the quad-ridged waveguide 110 and the feed structures 130a, 130b. For example, the OMT 120 may comprise three ports, wherein a main port 122 is coupled to the quad-ridged waveguide 110, a first lateral port is coupled to the first feed structure 130a, and an axial port is coupled to the second feed structure 130b. At least one pair of ports may be arranged coaxially. For example, the quad-ridged waveguide 110 may extend in an axial direction and be coupled to the OMT 120 at the main port 122. The OMT 120 may comprise an axial port opposite and coaxially to the main port 122. As a result, the second feed structure 130b is arranged coaxially to the quad-ridged waveguide 110 (at least in a vicinity to the OMT 120, i.e. when disregarding subsequent bending of the second feed structure 130b). The OMT 120 may comprise one or more lateral ports coupled to the first feed structure 130a. The one or more lateral ports may be oriented at a 90° angle (or any other angle such as 30°, 45°, 60°, or 120°) relative to the axial direction of the quad-ridged waveguide 110. As a result, the first feed structure 130a (which may comprise one or more waveguides) may be oriented perpendicular to the quad-ridged waveguide 110 (and optionally the second feed structure 130b) at least in a proximity of the OMT 120. The OMT 120 may have more than one lateral port (not shown in FIG. 1). For example, the OMT 120 may comprise a first and second lateral port, wherein the first and second lateral port may be arranged coaxially. As a result, waveguides coupled to such first and second ports may be arranged in a common plane.

It should be noted that the antenna structure 100 of FIG. 1 may optionally be supplemented by any of the features, functionalities and details disclosed herein, both individually and taken in combination.

### 1. Quad Ridge Horn Antenna (QHRA) Design

In the following, quad ridge horn antenna designs will be described. It should be noted that, optionally, any of the features, functionalities and details of these quad ridge horn antenna designs may optionally be introduced into any of the embodiments of the present invention, both individually and taken in combination.

Based on antenna review results, a design of a quad ridge horn antenna (QRHA) was developed for 24-53 GHz operation in assumption that a low-profile antenna housing is needed.

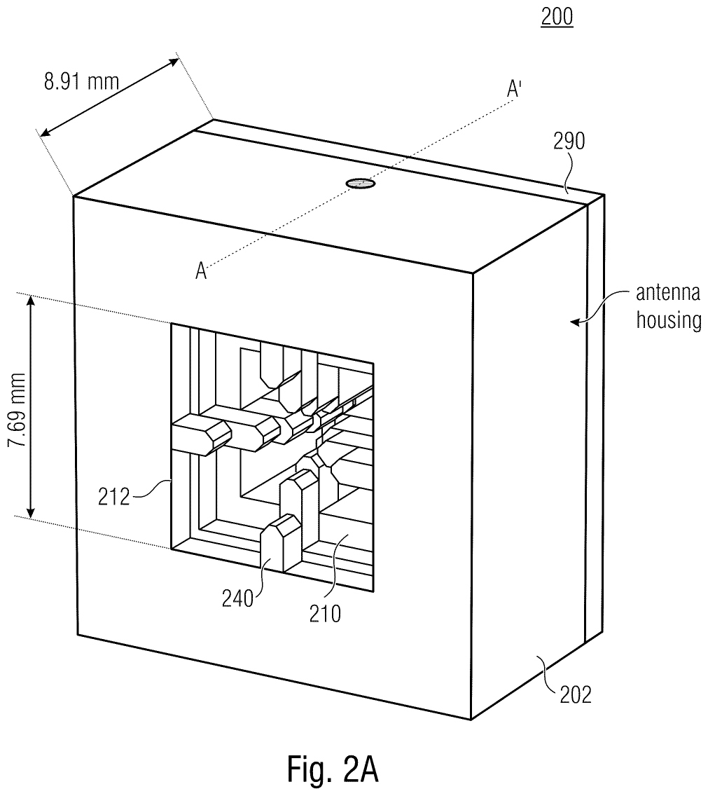

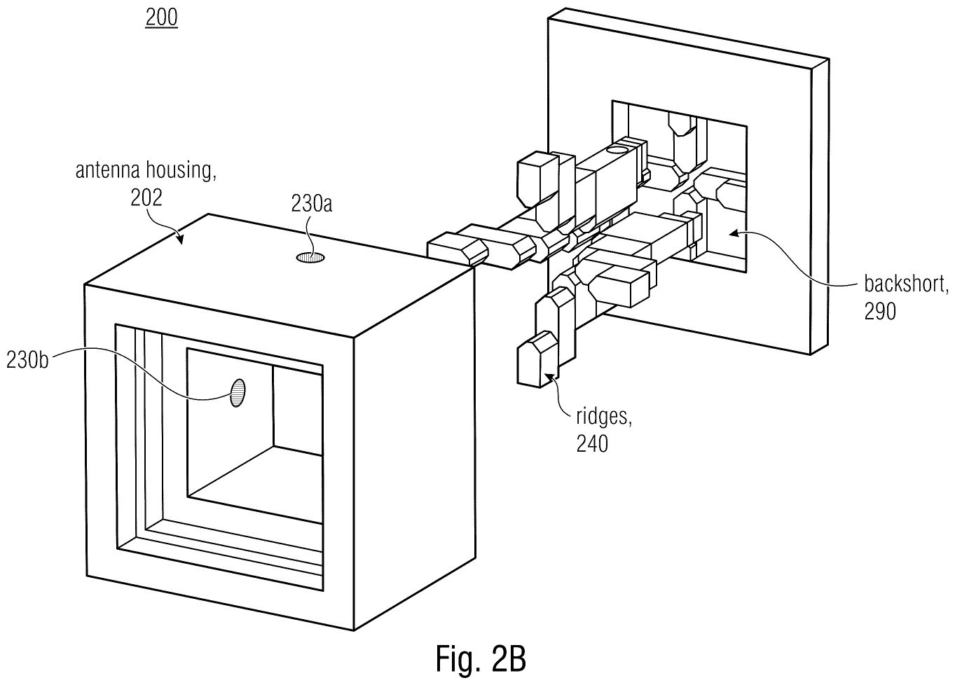

FIG. 2A shows an embodiment of an antenna device 200 in form of a quad ridge horn antenna design with a step-like ridges geometry. The antenna device 200 therefore has a quad-ridged waveguide 210 that comprises the quad ridge horn antenna and an radiating aperture 212 at an end face. A horn aperture is shortened with a step-like ridges geometry (see FIG. 2A) so as the antenna height is ˜9 mm only. It can be compatible with lower operational frequency of antenna is as high as 24 GHz (supporting lower frequencies may lead to increasing the horn aperture). Moreover, the stepped-ridge's shape is quite suitable for a computer numerical control (CNC)-milling process.

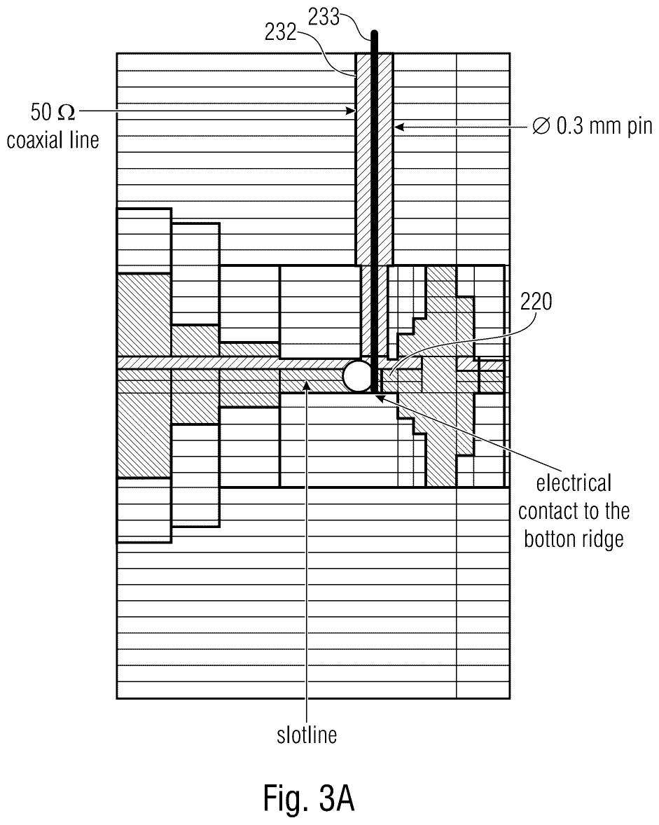

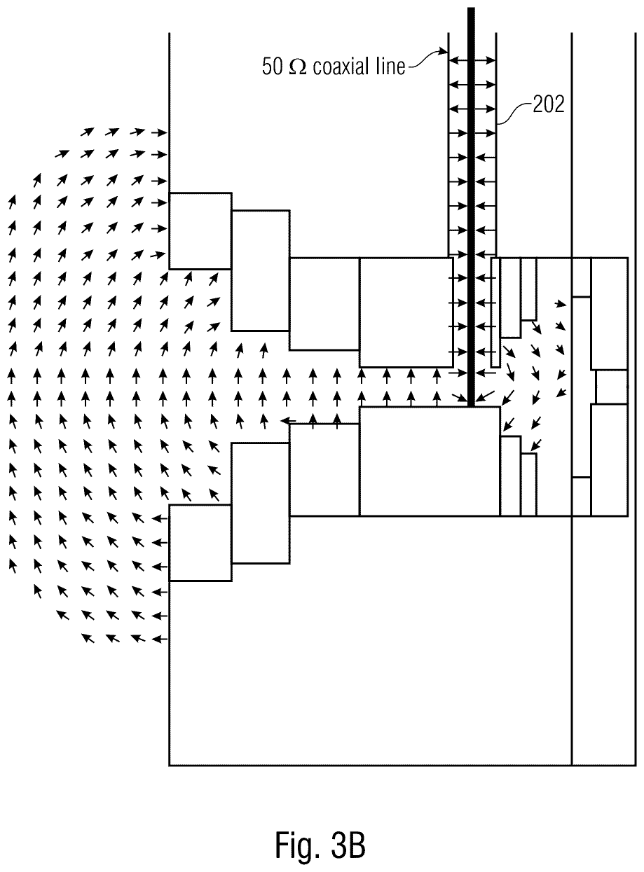

FIG. 2B shows a perspective assembly view of the QRHA depicted in FIG. 2A. FIG. 3A shows a cross-sectional view along a line A-A′ depicted in FIG. 2A.

The QRHA comprises an antenna housing 202, ridges 240, and a backshort 290. The antenna housing 202 comprising a first feed structure 230a and a second feed structure 230b. The first and second feed structures 230a, 230b are configured to receive a coaxial line or to form part of a coaxial line 232 (e.g., a 50Ω coaxial line).

For example the coaxial line 232 may be formed by an opening in in the antenna housing 202 and a pin 233, wherein the pin 233 may, for example, have a diameter of 0.3 mm (or another diameter between 0.1 and 1.0 mm). The pin 233 may, for example, reach and electrically contact a bottom ridge (e.g., a surface of a ridge 240 opposite of an opening for the coaxial line 232 inside the antenna housing 202). The antenna device 200 comprises an orthomode transducer 220 which couples to the first and second feed structures 230a, 230b.

FIG. 3B shows an electric field pattern of the cross-sectional view of FIG. 3A during coupling of an electromagnetic field via the coaxial line 232 into the antenna housing 202.

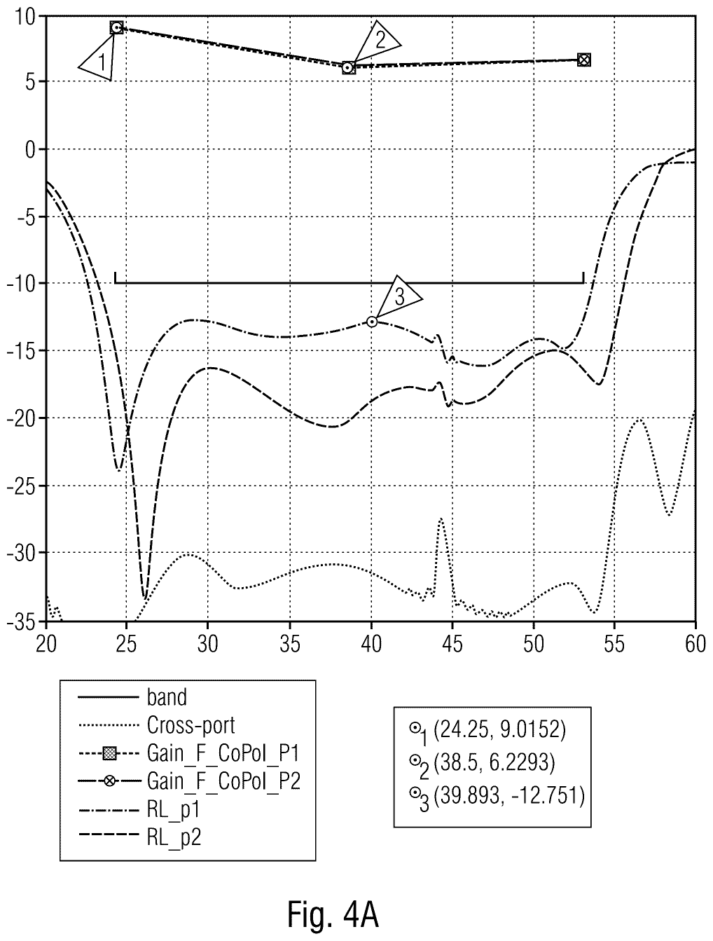

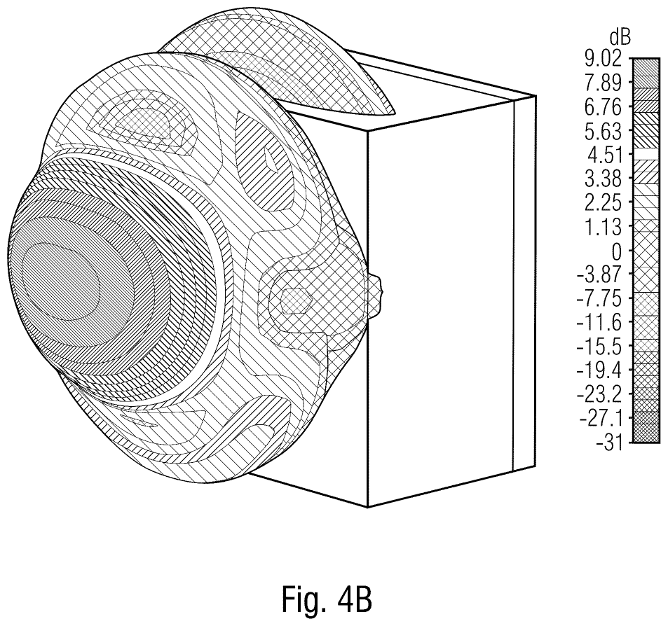

FIG. 4A shows a graphic representation of scattering parameters (S-parameters) and gain of a simulation of the QRHA depicted in FIGS. 2A to 3B.

FIG. 4B shows a graphic representation of a three dimensional far-field (3D FF) pattern of a simulation of the QRHA depicted in FIGS. 2A to 3B.

Simulated performance of the antenna shows 12 dB return loss (RL) over a 24-53 GHz band and <−30 dB cross-port talk (see FIG. 4A). The far-field pattern is smooth and symmetrical between both ports (e.g., coupled to the first and second feed structures 230a, 230b) with 6.1-9 dBi gain range and >25 dB cross-polarization discrimination in the boresight direction, in far-field.

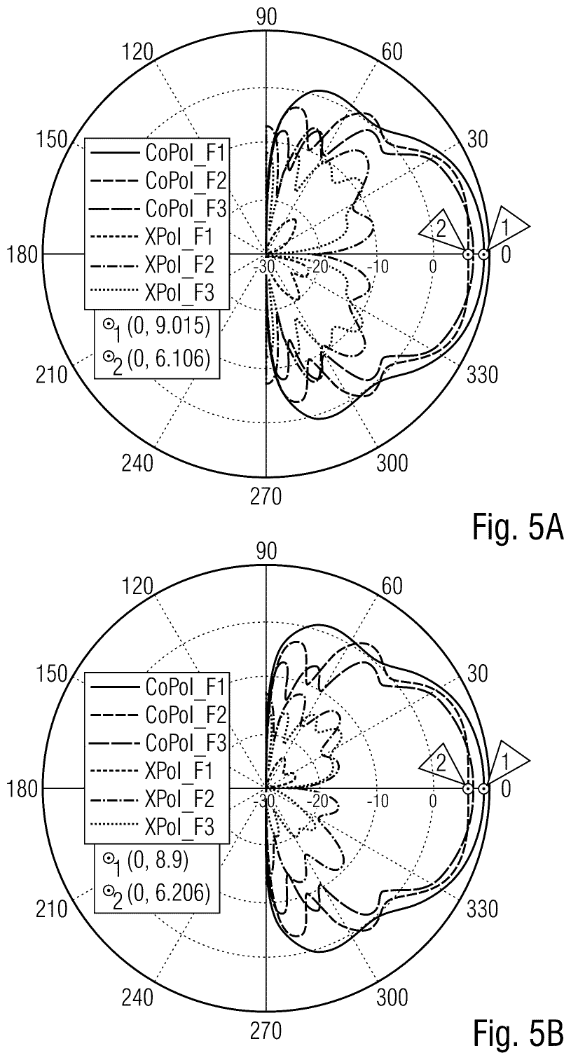

FIG. 5A shows a graphic representation of a far-field radiation pattern in polar coordinates comprising the first feed structure 230a when the antenna is fed through the first feed structure with three different frequencies F₁=24.25 GHz, F₂=38.5 GHz, F₃=53 GHz.

FIG. 5B shows a graphic representation of a far-field radiation pattern in polar coordinates comprising the second feed structure 230b when the antenna is fed through the second feed structure 230b with three different frequencies F₁=24.25 GHz, F₂=38.5 GHz, F₃=53 GHz.

It has been recognized that a coaxial connector may be less suitable to connect the measurement antenna in the handler arm to the automated test equipment (ATE) measurement test equipment in an automated high-volume manufacturing test cell, e.g. due to a complicated coupling procedure and wear caused by repeated coupling and uncoupling of the coaxial connector. Therefore, it has been recognized that a waveguide interface may be advantageous (or may even be needed in some cases).

Nonetheless, it has been recognized that the QRHA (e.g., antenna device 200) shows suitable performance and has very compact dimensions and low-profile. Furthermore, it has been recognized that the antenna device 200 allows receiving electrical fields with a different mode in each of the first and second feed structures 230a, 230b and transmitting a combination of the different modes at the radiating aperture 212 of the quad-ridged waveguide 210 (or vice versa).

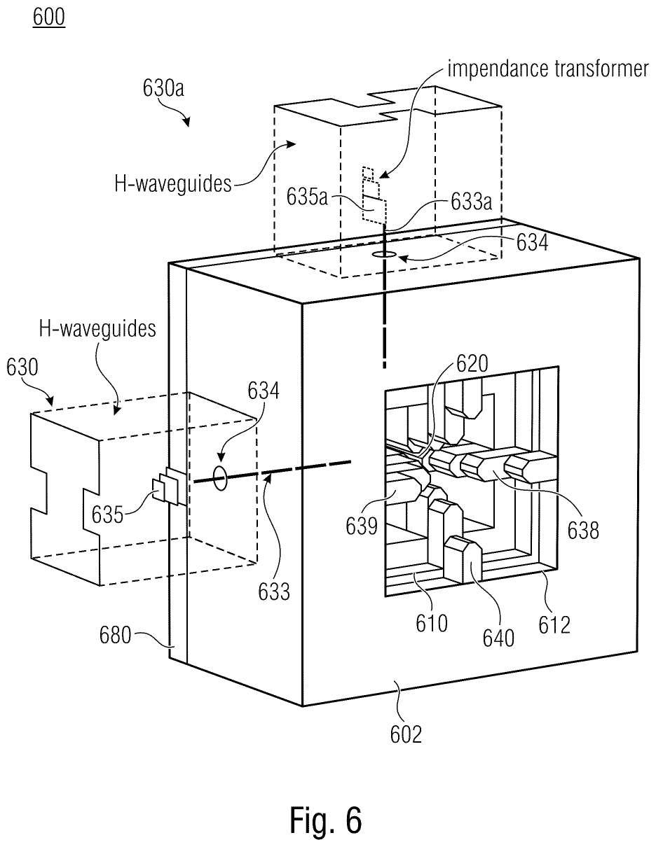

FIG. 6 shows an embodiment of an antenna device 600 with a quad ridged horn antenna concept with double-ridged waveguide interfaces. The antenna device comprises feed structures 620 coupled to a quad-ridged waveguide 610 and to first and second feed structures 630a, 630b, similar to the antenna device 200 shown in FIGS. 2A to 3B. The quad-ridged waveguide 610 has an end face with a radiating aperture 612. For example, the quad-ridged waveguide 610 comprises ridges 638,639.

Next, the idea of QRHA concept is further developed by attaching endlaunch waveguide adapters 634, 634a to coaxial ports (which may, for example, serve as feed structures), as depicted in FIG. 6. In this case, a center conductor of the coaxial feeding (e.g., pin 633 or pin 633a) extends towards the quad-ridged waveguide. For example, one of the pins (e.g. pin 633) is connected to one of the ridges (e.g. ridge 638). For example, in FIG. 3B it is seen the pin (e.g. pin 633) is connected mechanically and electrically to the opposite ridge (regarding to the hole in which the pin is inserted), e.g. to ridge 638. Moreover, for example, a respective center conductor of the coaxial feeding (e.g. pin 633 or pin 633a) may be connected to a respective impedance transformer (e.g. impedance transformer 635 or impedance transformer 635a) of the respective adapter 634a, 634a (e.g., first and second feed structures 630, 630a each comprising an endlaunch waveguide adapter 634, 634a and a pin 633, 633a).

It has been recognized that one drawback of the proposed concept depicted in FIG. 6 is the need of sophisticated mechanics because the respective pin 633, 633a may need to be accurately positioned in between miniature parts and ridges 640. Also, it has been recognized that a CNC milling process has limited applicability for antenna ridges manufacturing in a single piece, e.g., because of narrow slotlines (such as ˜0.5 mm width).

Thus, it has been recognized that multiple parts assemblies or a cutting wire process may be advantageous, or may even be the only applicable processes (critical) in some cases.

Finally, it has also been recognized that there may be extra return loss (RL) degradation for the hybrid antenna device, because additional endlaunch waveguide adapters 634, 634a are implemented.

### 2. Omt-Based Antennas

According to an aspect of the invention, it has been recognized that implementation of an orthomode transducers (OMT) in a dual polarized antenna design reduces the need of sophisticated coaxial feeding used in quad ridge horn antennas. In the following, aspects of the invention and embodiments according to the invention will be described. However, it should be noted that any of the features, functionalities and details disclosed herein may optionally be introduced into any of the embodiments of the present invention, both individually and taken in combination.

### 2.1 Boifot OMT

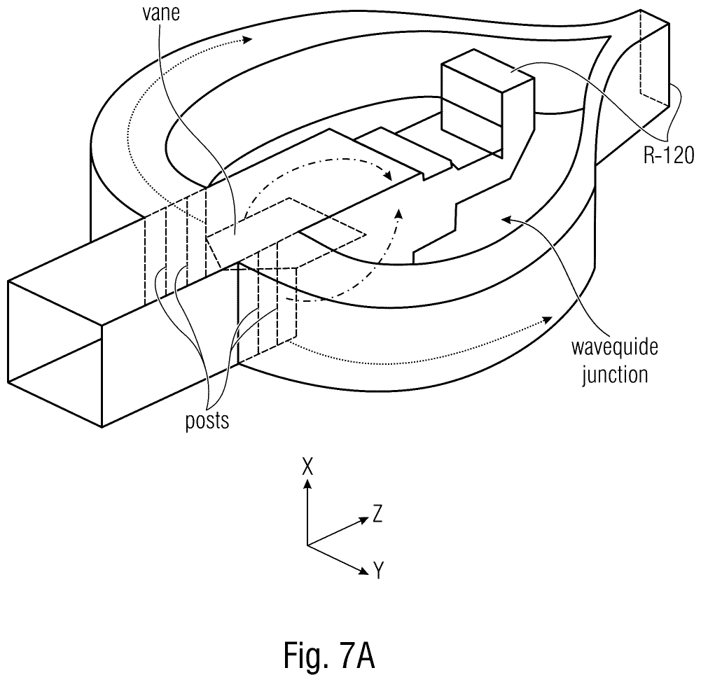

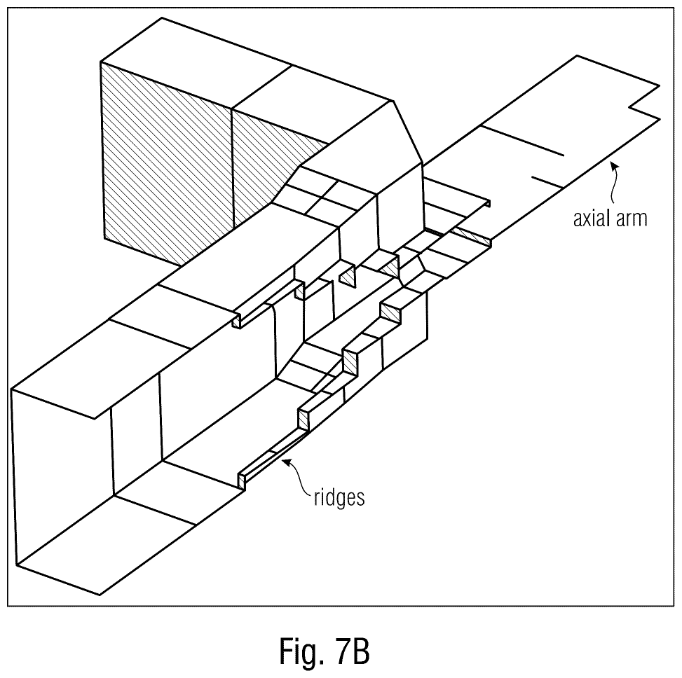

An OMT technique chosen for the antenna (or, generally speaking, useable in any of the antenna devices according to the present invention) is the so-called “Boifot” OMT design [1] (the design was called after the author of the work [1]) depicted in FIG. 7A. In a basic representation, the Boifot OMT is formed from a turnstile OMT by turning adjacent arms in an XZ plane (represented in FIG. 7A as arms in red and a dash-dotted line). Thus, it has been recognized that an overall feeding network can be disposed in a horizontal plane (e.g., a plane spanned by Z- and Y-axis). It has been recognized that this allows a significant improvement of Boifot OMT manufacturing because the OMT can be made in two (or more) milled housings.

It has been found that one drawback of the conventional Boifot OMT design is the need of a metallic wall between adjacent arms (so called vane or septum) and an extra waveguide junction for the vertical arms (e.g., the adjacent arms in the XZ plane, represented in red curves in FIG. 7A). These issues are solved in a double-ridged Boifot OMT modification [2]. FIG. 7B shows a cutplane view of such an OMT modification with stepped ridges that provide impedance transformation between double-polarized waveguide and the axial arm for the vertical polarization.

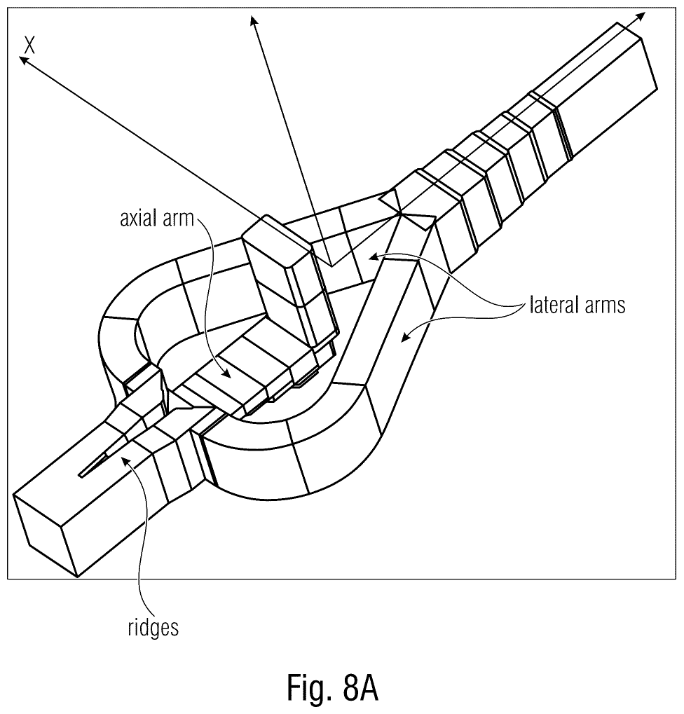

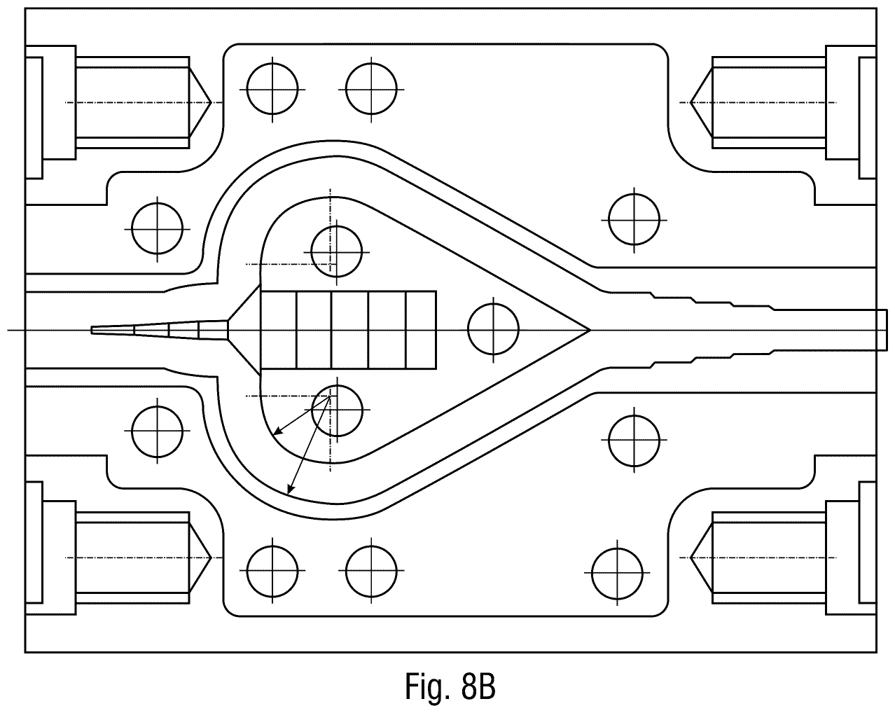

Hence, the double-ridged Boifot OMT (as depicted in FIG. 7B) does not need a vane/septum and extra T-junction for the vertical arms combining (compared to the one shown in FIG. 7A). In addition, vertical ridges can be naturally fabricated in a two-piece OMT housing as seen in form of a model in FIG. 8A and in form of a drawing shown in FIG. 8B. Many research works proved manufacturability and wideband performance of the double-ridged Boifot OMT design [3]-[7] so as its performance is similar to the classic turnstile OMT.

Therefore, it has been recognized that the presented design is interesting for the development of a solution to integrate a measurement antenna on a handler for an ATE test cell, considering, e.g., 5G FR2 application, with the following propositions:
Both feeding waveguide and dual-pol waveguide may be double-ridged waveguides because of extended bandwidth requirement;
Lateral arms routing (see FIG. 8A) may be re-designed for antenna housing to be made in axial “slices” (e.g. feeding waveguides and arms are disposed in the plane perpendicular to the dual-polarized waveguide or antenna aperture).

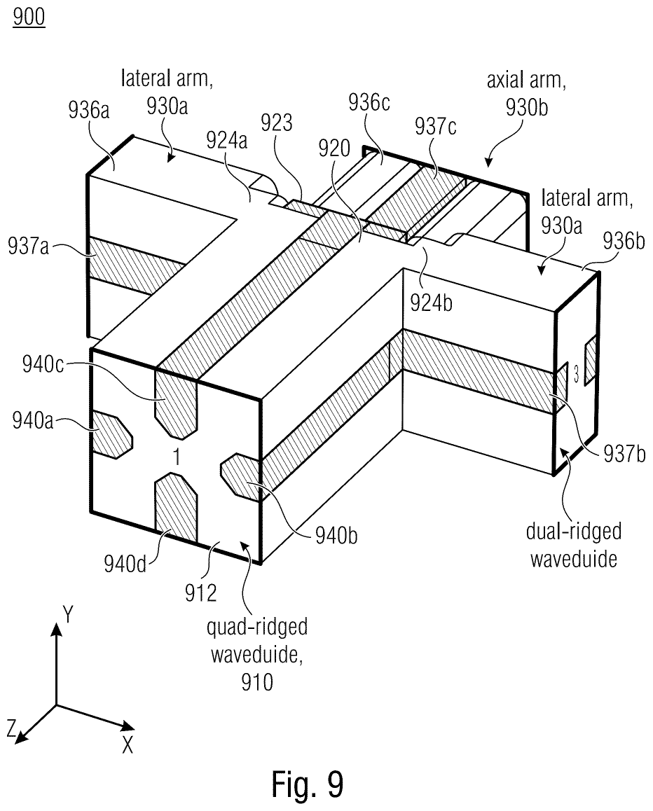

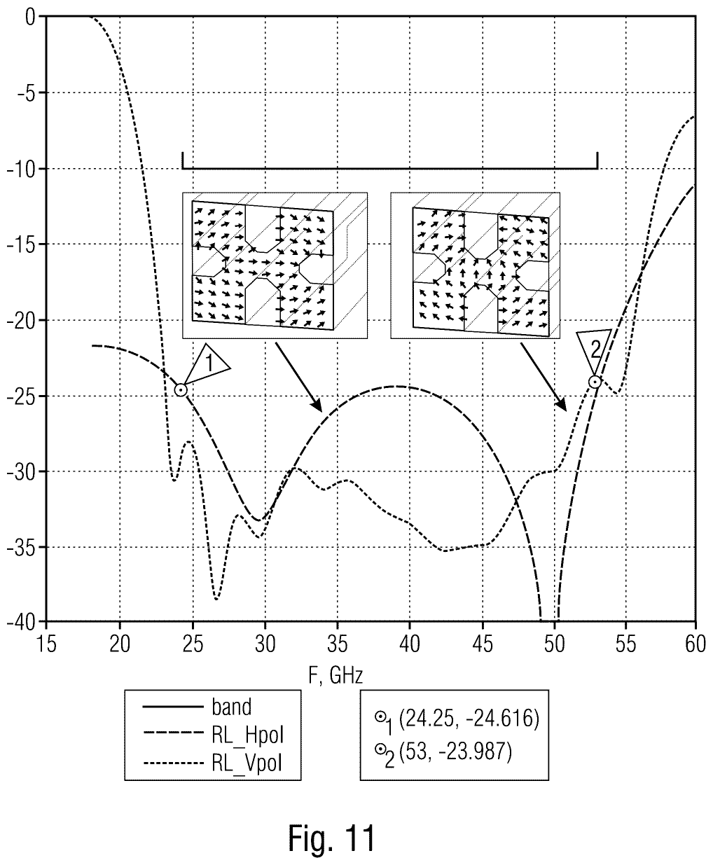

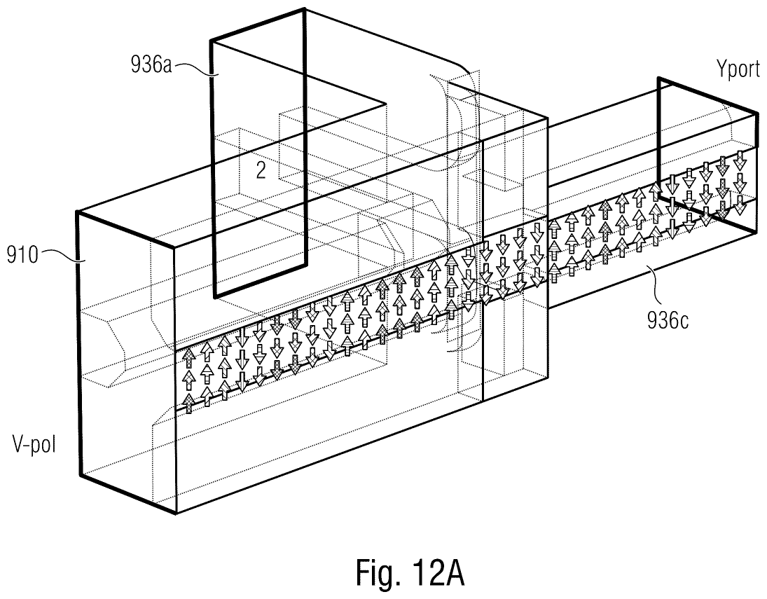

Therefore, considerations are directed at a quad-ridged square waveguide as a common dual polarized interface of the OMT (see FIG. 9). In fact, it has been found that ridges provide natural transformations for both: V-pol (e.g., vertically polarized electrical fields) to the axial arm and H-pol (e.g., horizontally polarized electrical fields) to the lateral arms (see FIG. 9). Thus, the quad-ridged Boifot OMT shows wideband performance: >20 dB RL in the needed band as depicted in FIG. 11.

FIG. 9 shows a perspective view of a further embodiment of the antenna device. The antenna device 900 is mostly defined by an inner hollow space, which is complicated to illustrate from the outside. Thus, FIG. 9 shows a perspective view, wherein inner hollow space and inner structures (e.g., ridges or waveguides) are both shown as solid volumes. Ridges 940a,940b,940c,940d, 937a,937b,937c are shown as grey volumes (e.g., volumes extending from inwards from inner surfaces) and hollow space is shown as blue volumes.

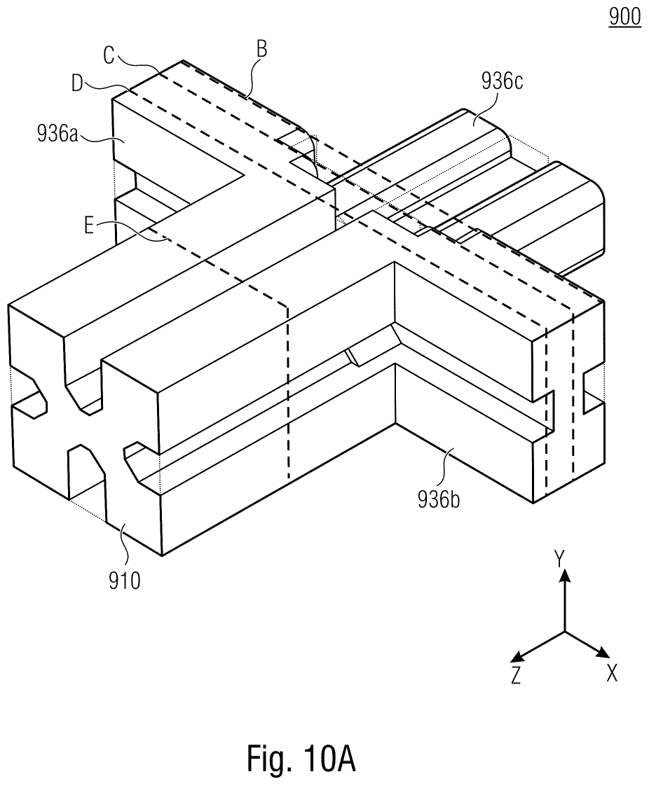

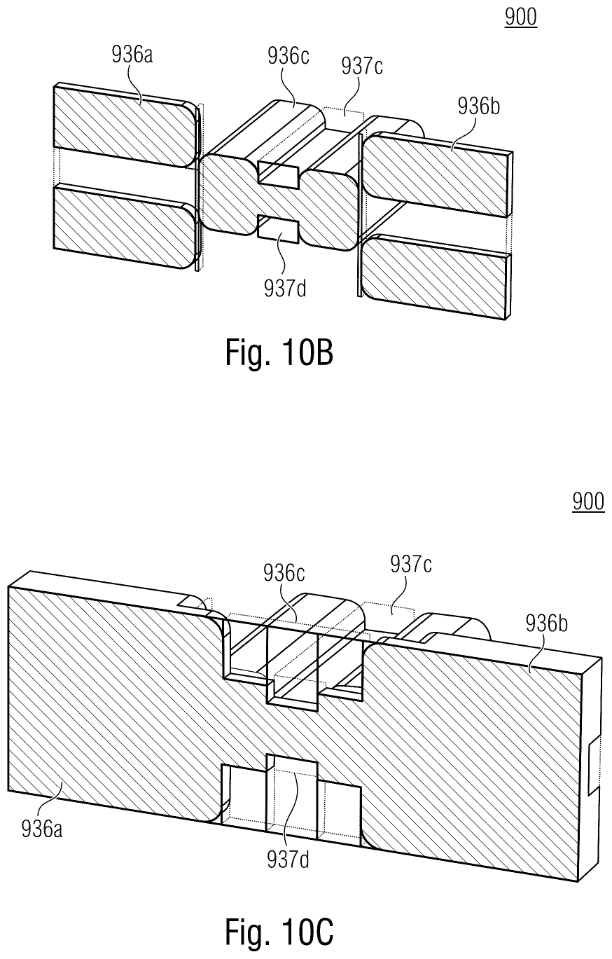

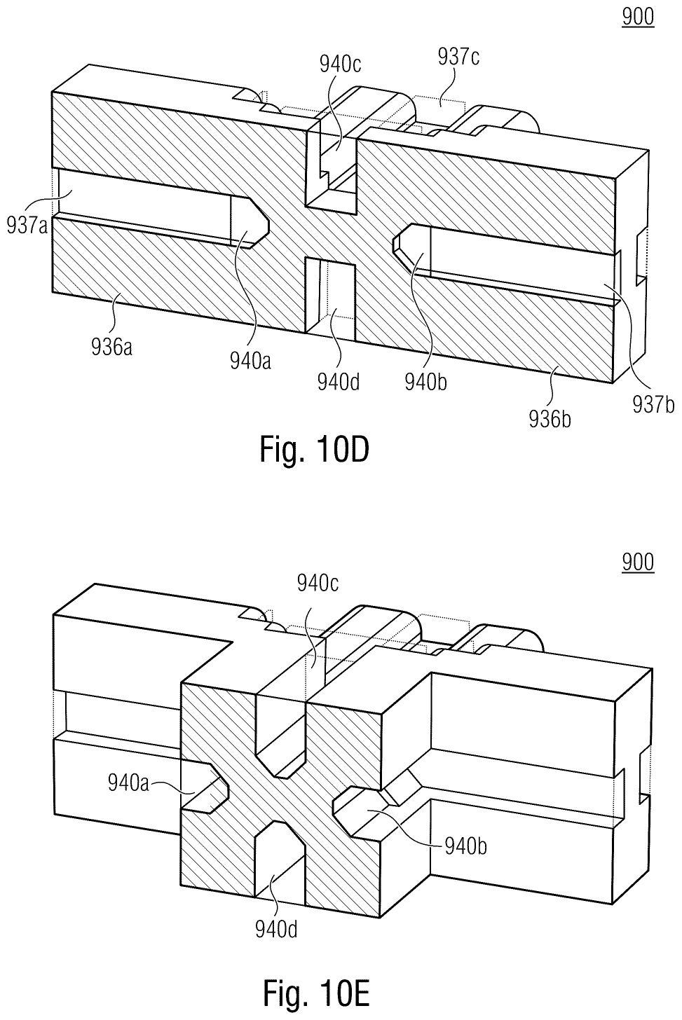

FIG. 10A shows a perspective view of an embodiment of the antenna device 900, wherein solid structures are not (or barely) visible, and FIGS. 10B to 10E show a perspective view of a cross section through different planes B to E of FIG. 10A. In other words, FIG. 10a illustrates hollow regions of the antenna device (i.e., waveguide's interior), while the material surrounding the hollow regions is omitted for the sake of visualization.

The antenna device 900 comprises a quad-ridged waveguide 910 coupled to an OMT 920. The quad-ridged waveguide 910 has an aperture 912, which can serve as a radiating aperture in some (simple) embodiments. The quad-ridged waveguide 910 is exemplarily depicted in FIG. 9 with a square shaped cross section, but may have any other shape (e.g. as described herein). The quad-ridged waveguide 910 comprises four ridges 940a-d. The ridges extend inwardly from the four peripheral surfaces of the cuboidal basic form of the waveguide 910. For example, the respective ridges are arranged along middle lines of respective peripheral surfaces of the basic form of the waveguide. For example the resulting waveguide may comprise symmetry with respect to two planes, wherein a first symmetry plane lies in the middle between two opposite peripheral surfaces of the cuboidal basic form, and wherein a second symmetry plane lies in the middle between two further opposite peripheral surfaces of the cuboidal basic form. The ridges shown in FIG. 9 have a similar shape, but different sizes. In particular, first and second ridges 940a, b are shorter (e.g. by at least 10 percent, or by at least 20 percent) (i.e. in an extension direction from its respective inner surface towards a center of the quad-ridged waveguide 910) than third and fourth ridges 940c, 940d. For example, a radial extension of the ridges 940a,940b (in FIG. 9 for the ridges 940a,940b in x-direction) may be smaller than one third of a total width of the waveguide (e.g. by at least 10 percent). In contrast, a radial extension of the ridges 940c,940d (in FIG. 9 for the ridges 940c,940d in y-direction) may be larger than one third of a total width of the waveguide (e.g. by at least 10 percent). Alternatively, the ridges 940a-d may have the same size as well as different shapes, or the same size and shape.

The ridges shown in FIG. 9 have a cuboid shape with a trapezoid cross section at a side facing a center of the quad-ridged waveguide 910. The ridges 940a-d may have different shapes, such as a cuboid shape with a semicircle cross section at the center side or only a cuboid shape. In some embodiments (e.g. in simple embodiments), the quad-ridged waveguide 910 has an end face (opposite the OMT 920), which forms an aperture 912 that can serve as a radiating aperture.

The antenna device 900 comprises a first feed structure 930a in form of (or comprising) two lateral arms. The first feed structure 930a comprises a first double-ridged waveguide 936a coupled to the OMT 920 at a first lateral port 924a and a second double-ridged waveguide 936b coupled to the OMT 920 at a second lateral port 924b. In the example shown in FIG. 9, the first and second double-ridged waveguides 936a, b are arranged coaxially relative to each other. The lateral ports 924a, b are arranged in a common plane. Furthermore, the first and second double-ridged waveguide 936a, b have at least essentially an identical shape and orientation of their cross-sections, wherein side faces of the first double-ridged waveguide 936a are arranged in same planes as corresponding side faces of the second double-ridged waveguide 936b. In other words, the first and second double-ridged waveguides 936a, b essentially form a single straight waveguide except for a discontinuity at the OMT 920.

The antenna device 900 further comprises a second feed structure 930b in form of (or comprising) an axial arm. The second feed structure 930b comprises a third double-ridged waveguide 936c. The third double-ridged waveguide 936c is coupled to the OMT 920 at an axial port 923. The third double-ridged waveguide 936c is, for example, arranged coaxially to the quad ridged waveguide 910. In other words, a center axis of the quad-ridged waveguide 910 coincides, for example, with a center axis of the third double-ridged waveguide 936c. Furthermore, the third double-ridged waveguide 936c is arranged in such a way that its two ridges (e.g. ridge 937c and another ridge opposite of ridge 937c and not visible in FIG. 9) are arranged in a common plane (e.g., Y-Z-plane) with two ridges (e.g., ridges extending in a vertical direction) (e.g. ridges 940c,940d) of the quad ridged waveguide 910. However, the third double-ridged waveguide 936c and the quad ridged waveguide 910 may optionally be oriented differently. The third double-ridged waveguide 936c has a rectangular cross section (by its outer contour) with two wide sides and two narrow sides (or peripheral surfaces of the basic form), wherein a width of the wide side (e.g., parallel to a X-Z-plane) is, for example, at least essentially identical to one width of quad ridged waveguide 910. Furthermore, the wide side is arranged parallel to a side of the quad ridged waveguide 910.

The antenna device 900 essentially forms a cross with the OMT 920 in the middle, wherein the quad ridged waveguide 910 and the third double-ridged waveguide 936c extend at a 90° angle relative to the first and second double-ridged waveguides 936a, b.

The ridges of the first and second double-ridged waveguides 936a, b extend in a common plane (e.g., parallel to the X-Z-plane). However, the ridges of the third double-ridged waveguide 936c extend in a plane that is oriented perpendicular (e.g., parallel to the Y-Z-plane) to the common plane of the ridges of the first and second double-ridged waveguides 936a, b.

The first lateral port 924a of the OMT 920 comprises a transition between the quad-ridged waveguide 910 and the first double-ridged waveguide 936a, wherein a first ridge 940a of the quad-ridged waveguide 910 transitions into a first ridge 937a of the first double-ridged waveguide 936a (e.g. the first ridge 940a of the quad-ridged waveguide lies in a same plane as the first ridge 937a of the first double-ridged waveguide 936a).

The second lateral port 924b of the OMT 920 comprises a transition between the quad-ridged waveguide 910 and a second double-ridged waveguide 936b, wherein a second ridge 940b of the quad-ridged waveguide 910 (which is opposite to the first ridge 940a of the quad-ridged waveguide 910 in the example shown in FIG. 9) transitions into a first ridge 937b of the second double-ridged waveguide 936b (e.g. the second ridge 940b of the quad-ridged waveguide 910 lies in a same plane as the first ridge 937b of the second double-ridged waveguide 936b). The first ridge 940a of the quad-ridged waveguide 910, the second ridge 940b of the quad-ridged waveguide 910, the first ridge 937a of the first double-ridged waveguide 936b and the first ridge 937b of the second double-ridged waveguide 936b may all lie within a same (first) plane.

The axial port 923 of the OMT 920 comprises a transition between the quad-ridged waveguide 910 and the third double-ridged waveguide 936c, wherein a third ridge 940c of the quad-ridged waveguide 910 transitions into a first ridge 937c of the third double-ridged waveguide 936c, and wherein a fourth ridge 940d of the quad-ridged waveguide 910 transitions into a second ridge 937d (see in FIG. 10B) of the third double-ridged waveguide 936c. The third ridge 940c of the quad-ridged waveguide 910, the fourth ridge 940d of the quad-ridged waveguide 910, the first ridge 937c of the third double-ridged waveguide 936c and the second ridge of the third double-ridged waveguide 936c all lie within a same (second) plane. In the embodiment depicted in FIG. 9, the second plane is perpendicular to the first plane.

FIG. 10A shows the antenna device 900 with four planes B to E that cross the antenna device 900. Cross-sections of the antenna device 1000 generated by the planes B to E are shown in FIGS. 10B to 10E.

FIG. 10B shows a cross-sectional view of the antenna device 900 through the plane B. Plane B crosses the first and second double-ridged waveguides 936a, b at a ridge. Therefore, only portions (e.g. hollow, wave-guiding portions) above and below the ridge of the first and second double-ridged waveguides 936a, b can be seen in FIG. 10B. FIG. 10B further shows the cross section of the third double-ridged waveguide 936c, which is a double-ridged waveguide (and which may, for example, comprise an “H”-like shape of the wave-guiding structure). Corners of the cross-sectional shape of the third double-ridged waveguide 936c may be rounded, as seen in FIG. 10B. The round corners may be the result of a milling tool dimensions or milling tool trajectory. However, any corner of the antenna device 900 may be rounded or angular. The ridges 937c, 937d of the third double-ridged waveguide 936c have a rectangular cross section or an approximately rectangular cross section, optionally with a flared base (as seen in FIG. 10B). However, any ridge of the antenna device 900 may have no flared bases as exemplarily seen for the ridges of the first and second double-ridged waveguides 936a, b (e.g., see FIG. 9 or 10A).

FIG. 10C shows a cross-sectional view of the antenna device 900 through the plane C, which essentially crosses the antenna device 900 between ridges of the first and second double-ridged waveguides 936a, b. Therefore, the inner hollow space has lateral portions of the cross-section in FIG. 10C that extend along an entire width of the first and second double-ridged waveguides 936a, b. However, the inner hollow space is narrowed down to the cross section of the third double-ridged waveguide 936c, where the inner hollow space meets the third double-ridged waveguide 936c. As a result, the inner hollow volume is narrowed down in two steps, starting from a width of the wide side of the first and second double-ridged waveguides 936a, b narrowing down a first time to the width of the short side of the third double-ridged waveguide 936c and a second time to a width between the ridges 937c, 936d of the third double-ridged waveguide 936c.

FIG. 10D shows a cross-sectional view of the antenna device 900 through the plane D, which crosses the first and second double-ridged waveguides 936a, b at ridges 937a, b opposite the third double-ridged waveguide 936c. The cross section of FIG. 10D is similar to the one shown in FIG. 10B, as it shows inner hollow space of the first and second double-ridged waveguides 936a, b above and below their respective ridges. However, FIG. 10D shows an intersection with the quad-ridged waveguide 910 (instead of the third double-ridged waveguide 936c as shown in FIG. 10B). Therefore, FIG. 10D shows the transition between the first ridge 940a of the quad-ridged waveguide 910 into the first ridge 937a of the first double-ridged waveguide 936a and the transition between the second ridge 940b of the quad-ridged waveguide 910 into the first ridge 937b of the second double-ridged waveguide 936.

FIGS. 10B to 10D also show that the ridges 937c, 936d of the third double-ridged waveguide 936c transition into the third ridge 940c and fourth ridge 940d of the quad-ridged waveguide 910.

FIG. 10E shows a cross-sectional view of the antenna device 900 through the plane E, which crosses the quad-ridged waveguide 910. As can be seen, the ridges of the first, second, and third double-ridged waveguides 936a-c that transition into the ridges 940a-d are continued along an extension of the quad-ridged waveguide 910.

In the example shown in FIGS. 10B to E, the shape of the ridges changes slightly, as the first ridge 937c of the third double-ridged waveguide 936c has a shape of rectangle with a flared base (see FIG. 10B), which transitions into a purely rectangular shape (see FIG. 10D, reference numeral 940c), which then transitions into a rectangle with a trapezoid (see FIG. 10E, reference numeral 940c). Therefore, the ridges may have different shapes during transitioning. Alternatively, the shape of any of the ridges may stay at least essentially identical during transitioning (e.g., having one of the three shapes described above along an entire transition between the quad-ridged waveguide 910 and the third double-ridged waveguide 936c).

FIGS. 9 to 10E show no tapering of the ridges 940 (940a-940d) of the quad-ridged waveguide 910. However, the ridges 940 may not have or have a (e.g., stepwise) tapering (such as shown in FIG. 6).

To conclude, FIG. 9 shows an antenna device 900. For example, in simple embodiments, the aperture 912 can serve as a radiating aperture. The antenna device 900 shown in FIG. 9 is based on an orthomode transducer. Thus, in general, the radiating aperture 912 may be a quad-ridged port of OMT, or may be coupled to a quad-ridged port of the OMT.

In implementations, a horn-shaped extension may be attached (e.g. to the quad-ridged port 910 of the orthomode transducer OMT), and an antenna effect occurs (or is improved).

To further conclude, radiating aperture 912 may be a quad-ridged waveguide's (910) port and/or a dual-polarized waveguide port.

FIG. 11 shows a graphic representation of simulated reflection coefficients (S₁₁, S₂₂) for horizontal and vertical polarizations. As can be seen, the return loss is particularly high (e.g. >20 dB) for the 24-53 GHz band.

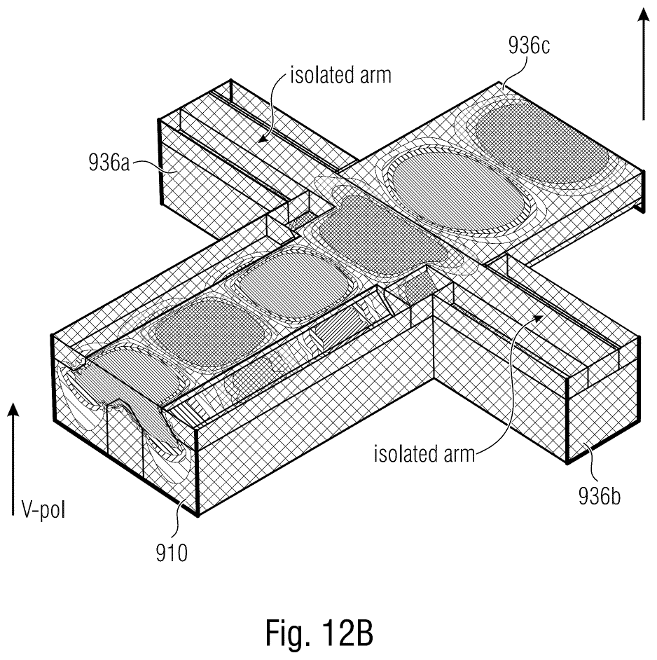

FIG. 12A shows a result of a simulation of an E-field vector pattern for vertical polarization (first polarization) of a vertical cross section through the antenna device 900.

FIG. 12B shows a result of a simulation of the E-field pattern for vertical polarization of a horizontal cross section through the antenna device 900.

The E-field with the vertical polarization is largely contained within the quad-ridged waveguide and within the third double-ridged waveguide 936c (e.g., the Y-port), and with (next to) no excitement in the first and second double-ridged waveguides 936a, b. Therefore, the first and second double-ridged waveguides 936a, b are well isolated from the quad-ridged waveguide 910 and from the third double-ridged waveguide 936c when a vertically polarized electric field is coupled between the quad-ridged waveguide 910 and the third double-ridged waveguide 936c.

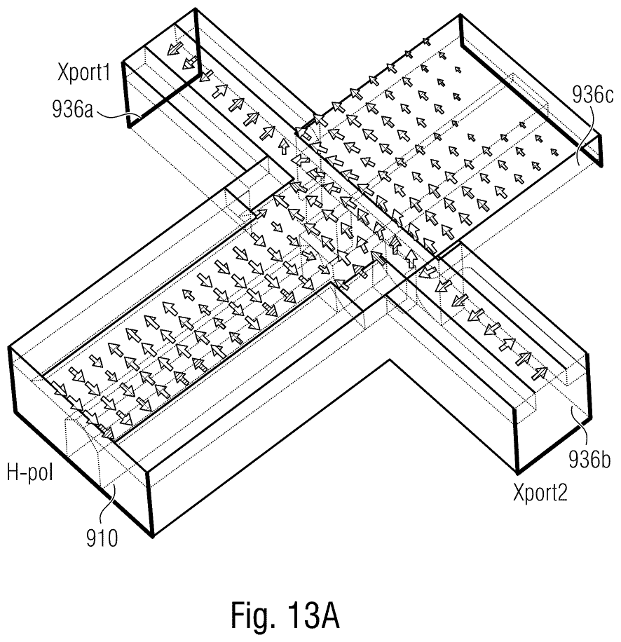

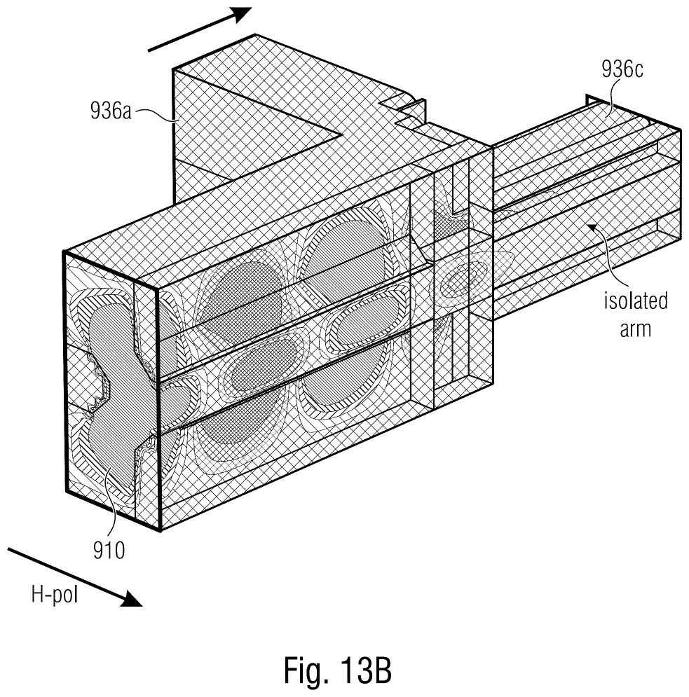

FIG. 13A shows a result of a simulation of an E-field vector pattern for horizontal polarization (second polarization) of a horizontal cross section through the antenna device 900.

FIG. 13B shows a result of a simulation of the E-field pattern for horizontal polarization of a vertical cross section through the antenna device 900.

The E-field with the horizontal polarization is largely contained within the quad-ridged waveguide and within the first and second double-ridged waveguides 936a, b (e.g., the Xport1 and Xport2) and with (next to) no excitement in the third double-ridged waveguide 936c. Therefore, the third double-ridged waveguide 936c is well isolated from the first and second double-ridged waveguides 936a, b when a horizontally polarized electric field is coupled between the quad-ridged waveguide 910 and the first and second double-ridged waveguides 936a, b.

Notably, the simulated cross-port isolation (which is typically a positive number) is very good (e.g. >80 dB) (or in other words, cross-port transmission or cross port talk (S21) is negligible) because of complete symmetry of the OMT model (>80 dB by simulations). It should be noted that (cross-port) isolation is a positive number (e.g. when measured in decibels), for example >80 dB, and that the cross-port talk (e.g. S21) is a negative value (e.g. when measured in decibels), for example <−80 dB. E-field pattern of the vertical polarization depicted in FIG. 12A, B shows lateral arms are isolated in this case. Vice versa, horizontal polarization of the quad-ridged waveguide is effectively matched with the lateral arms pair (e.g., first and second double-ridged waveguides 936a, b), whereas an Y-port (e.g., the third double-ridged waveguide 936c) becomes the isolated arm (FIG. 13B, C).

These results show that the quad-ridged modification of Boifot OMT is effective in reaching more than an octave bandwidth and high polarization discrimination, whereas the design does not require a septum or an additional waveguide junction as there is only one axial arm (e.g., the third double-ridged waveguide 936c).

From the mechanical point of view, the OMT housing may need considerations because a quad of ridges may be difficult to be milled in a two parts housing separated in the YZ plane as shown in FIG. 8B.

### 2.2 Dual-Polarized Waveguide Antenna Based on the Quad-Ridged Boifot OMT

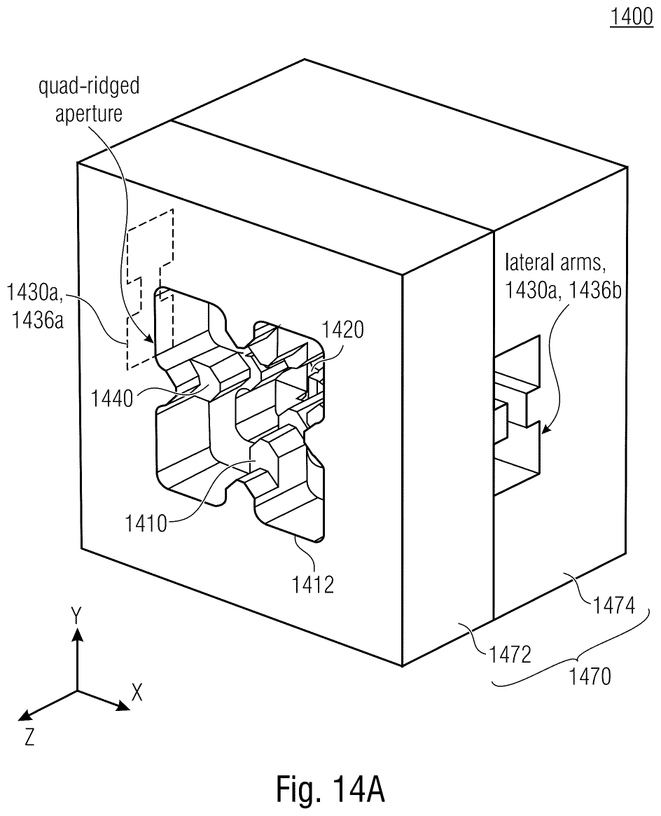

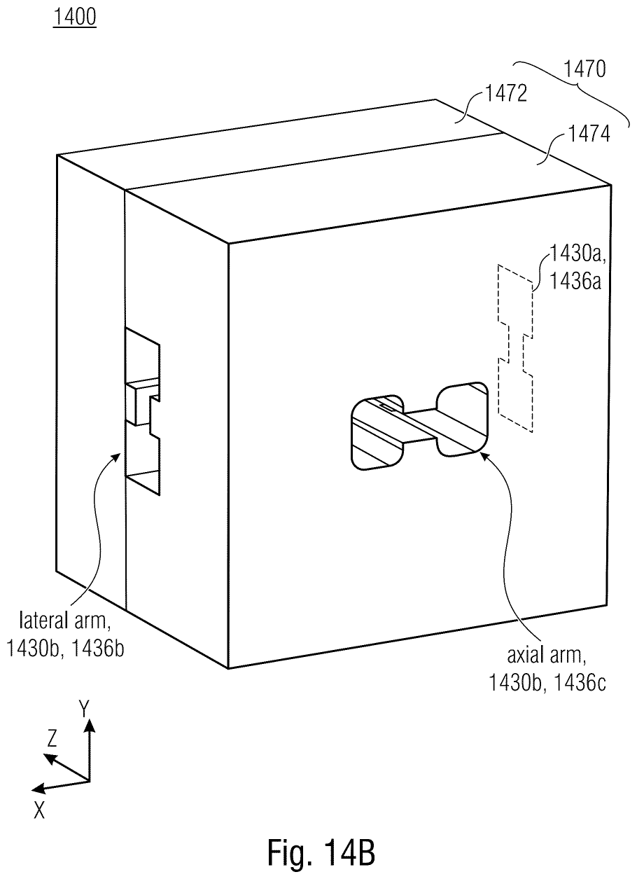

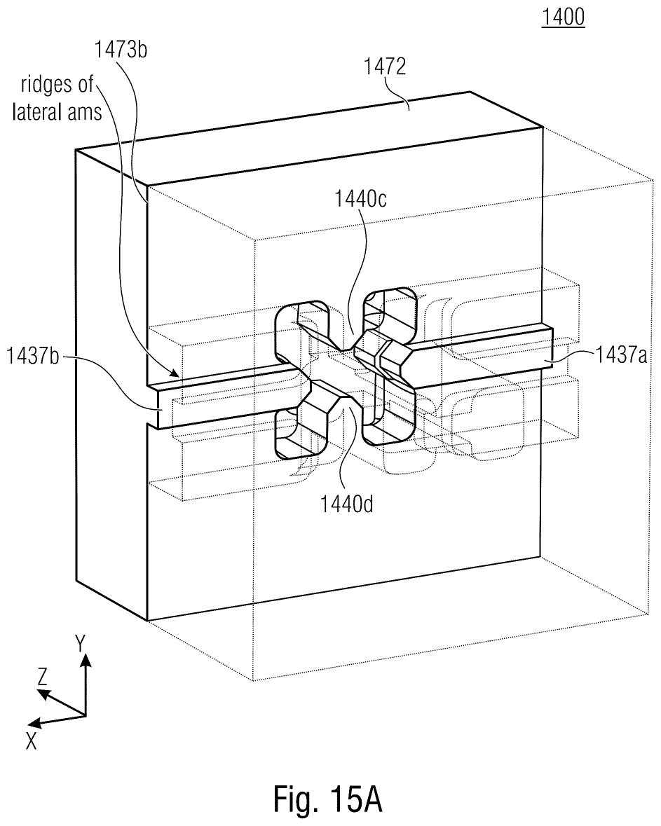

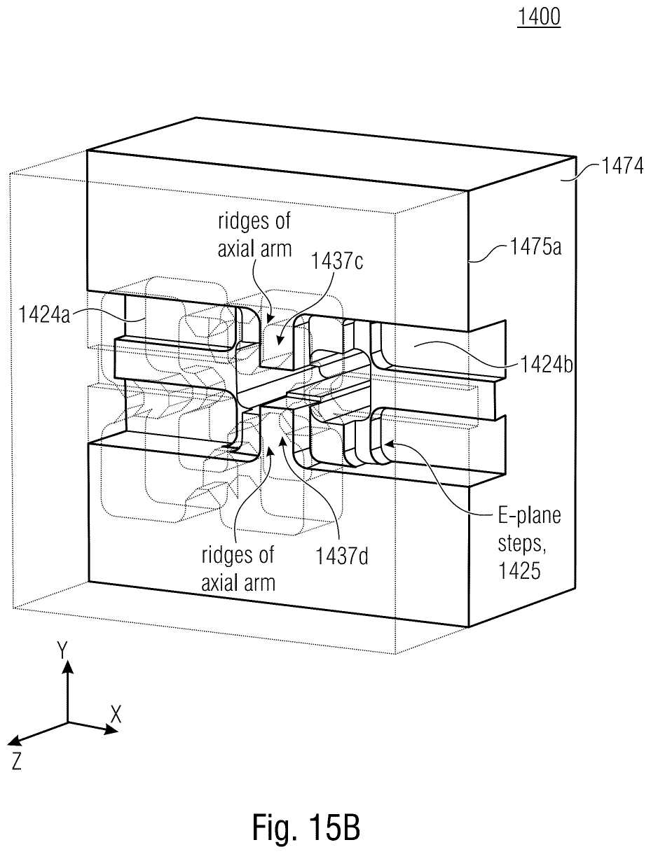

FIGS. 14A to 15B show a perspective view of a solid model of the dual-polarized waveguide antenna based on the quad-ridged Boifot OMT, according to an embodiment of the present invention.

FIG. 14A shows a perspective view of a further embodiment of an antenna device 1400, providing a view of a quad-ridged aperture with a quad-ridged waveguide 1410 and a lateral arms. The lateral arms may comprise a first feed structure 1430a, for example, with a first double-ridged waveguide 1436a (indicated with dashed lines in FIG. 14A) and a second double-ridged waveguide 1436b. The quad-ridged waveguide 1410 may be used to feed the radiating aperture 1412 as shown in FIG. 14A. The quad-ridged waveguide 1410, the first double-ridged waveguide 1436a and the second double-ridged waveguide 1436b are coupled to an OMT 1420.

The antenna device 1400 is implemented in an antenna housing 1470, wherein the antenna housing 1470 comprises two portions in form of a first housing portion 1472 and a second housing portion 1474. The antenna housing 1470 (or at least one portion thereof) may comprise (or consist of) a metal structure in which at least one of the quad-ridged waveguide 1410, the OMT 1420, the first and second feed structures 1430a, b are formed (or in which all of the quad-ridged waveguide 1410, the OMT 1420, the first and second feed structures 1430a, b are formed). The first and second housing portions 1472, 1474 (and optional further housing portions) may be provided as at least two structured metal layers stacked on top (and optionally attached) to each other.

FIG. 14B shows a perspective view of the antenna device 1400 of FIG. 14A, providing a view of the lateral arm (e.g., the first feed structure 1430a comprising the first and second double-ridged waveguides 1436a, b) and an axial arm (e.g., a second feed structure 1430b comprising a third double-ridged waveguide 1436c). The second feed structure 1430b is provided (at least partially) in the second housing portion 1474.

FIG. 15A shows a perspective view of the antenna device 1400 of FIG. 14A, providing a view of a first inner surface 1473b of the first housing portion 1472 facing a semi-transparently illustrated version of the second housing portion 1474.

The first housing portion 1472 comprises first ridges 1437a, 1437b of the first feed structure 1430a (e.g., of a first and second double-ridged waveguide).

FIG. 15B shows a perspective view of the antenna device 1400 of FIG. 14A, providing a view of an inner surface 1475a of the second housing portion 1474 facing a semi-transparently illustrated version of the first housing portion 1472.

The second housing portion 1474 comprises a first ridge 1437c and a second ridge 1437d of the second feed structure 1430b (e.g., a third double-ridged waveguide). When the first and second housing portions 1472, 1474 are combined, faces of the first and second ridge 1437c, d of the second feed structure 1430b can abut against faces of a third and fourth ridge 1440c, d of the quad-ridged waveguide 1410. As a result, the first ridge 1437c of the second feed structure 1430b transitions into the third ridge 1440c of the quad-ridged waveguide 1410 and the second ridge 1437d of the second feed structure 1430b transitions into the fourth ridge 1440d of the quad-ridged waveguide 1410.

It should be noted that the first and second housing portions 1472, 1474 can be separated at other surfaces (e.g., by translating a separating surface somewhere along the Z-axis, i.e. in axial direction). However, manufacturing (e.g., milling and/or micromachining) and/or assembly of the antenna housing 1470 can be less complex, if at least one of the inner surfaces 1473b, 1475a (along which the antenna housing 1470 is separated) align with structural surfaces (e.g., a broad wall of a double-ridged waveguide) inside the antenna housing 1470. In the example shown in FIGS. 14A to 15A, the first and second housing portions 1472, 1474 may comprise structural surfaces of the first feed structure 1430a such that the first inner surface 1473b aligns (or lies flush with) a wide inner surface of the first feed structure 1430a.

The second housing portion 1474 comprises E-plane steps 1425 that are arranged at lateral ports 1424a, b (or at the OMT 1420). The E-plane steps 1425 are configured to stepwise narrow/taper a shorter width (e.g., an extension in the Z-direction) of the first feed structure 1430a (e.g., a width of first and second double-ridged waveguides thereof) along a direction towards (or dependent on a distance to) a first and second ridge 1437c, d of the second feed structure 1430b (or towards a center, or central region, of the OMT). In the example depicted in FIG. 15B, the E-plane steps 1425 comprise, for example, two steps. The first step has, for example, a rise height equal to a height of a ridge of the first and second double-ridged waveguide 1436a, b. And the second step has, for example, a rise height equal to the one of the first step. However, any other number of steps with any other rise (e.g., equal or different rise) may be used instead.

A transition between the quad-ridged waveguide 1410 and the radiating aperture 1412 may be formed, for example, by tapered waveguide steps and ridges similar to the QRHA design mentioned in § 1 (see FIGS. 2A to 6). The quad-ridged aperture 1409 enables the use of the antenna device 1400 over a very wide frequency range and provides an effective design of a dual-polarized waveguide antenna based on the developed OMT. Both: a section of a quad-ridged waveguide 1410 and the quad-ridged aperture 1409 can be milled in the first housing portion 1472. It should be noted that for the milling process, all internal corners may be rounded with a tool radius (typical 0.5 mm). Alternatively or additionally, a cutting wire process can be implemented to save sharp edges.

In the back side, the first housing portion 1472 serves as a cap of double-ridged waveguides of the lateral arms (see FIG. 15A). Also, for a smooth impedance transformation, there are E-plane waveguide steps 1425 in a joint of lateral arms and the quad-ridged waveguide 1410 (see FIG. 15B). This allows to excite a horizontal (X-axis) polarization in the quad-ridged aperture 1409 when out-of-phase signals (λ/2+2πn) are supplied to the lateral arms 1430a.

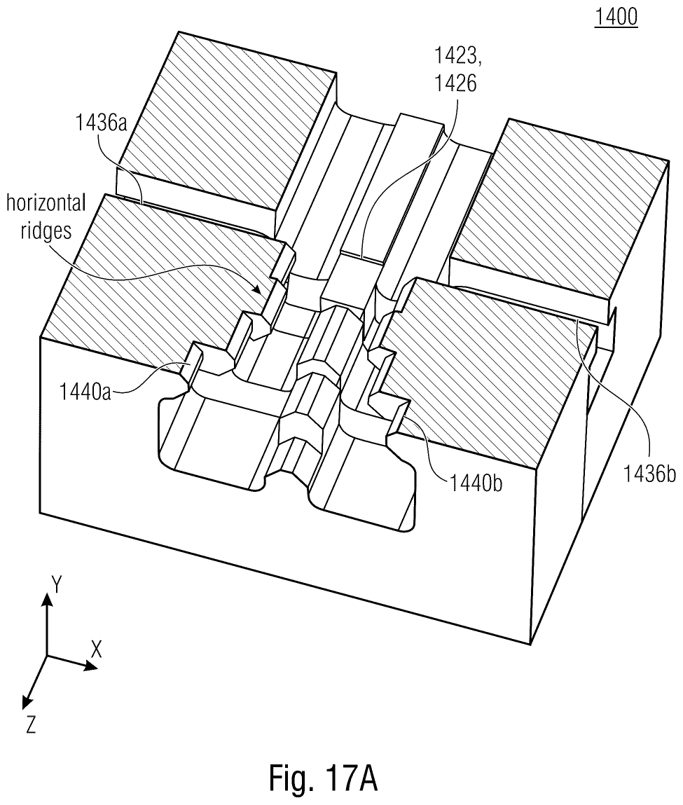

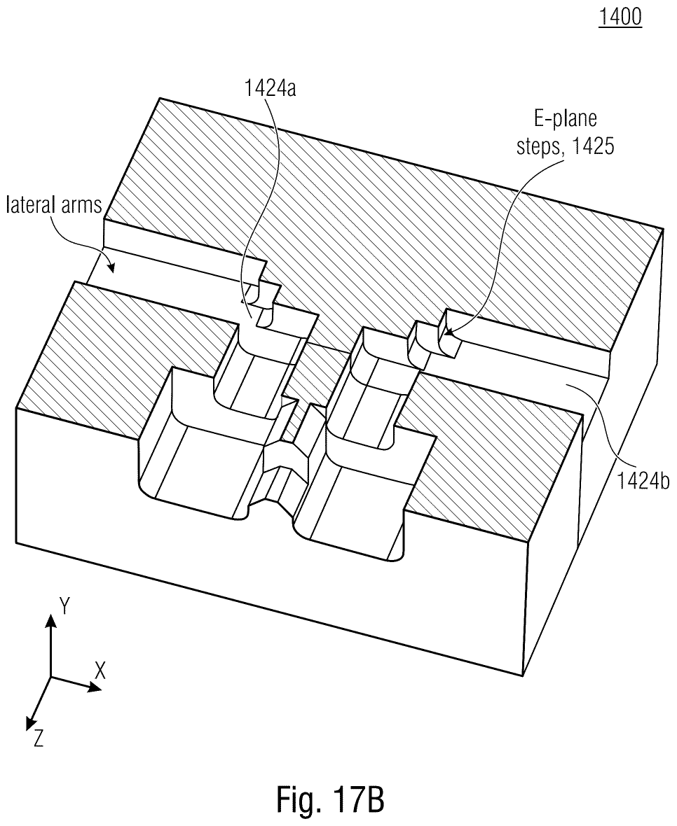

For a smooth transformation of vertical polarization (Y-axis), the ridges of the axial arm 1430b are connected to the vertical pair of ridges in quad-ridged aperture 1409 via a ridge step 1426 (FIG. 17A). The ridges of the axial arm are made in the second housing portion 1474 (see FIG. 15B).

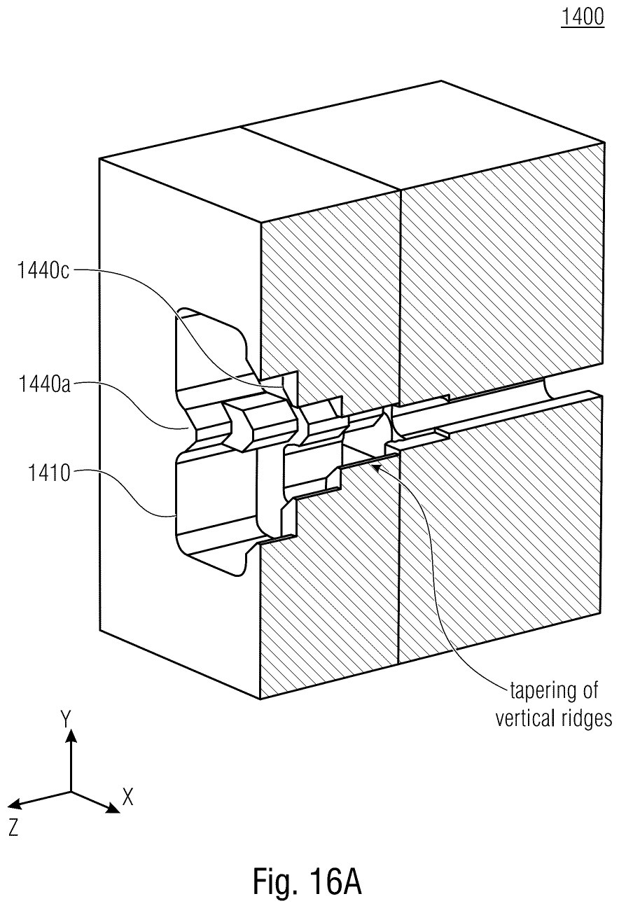

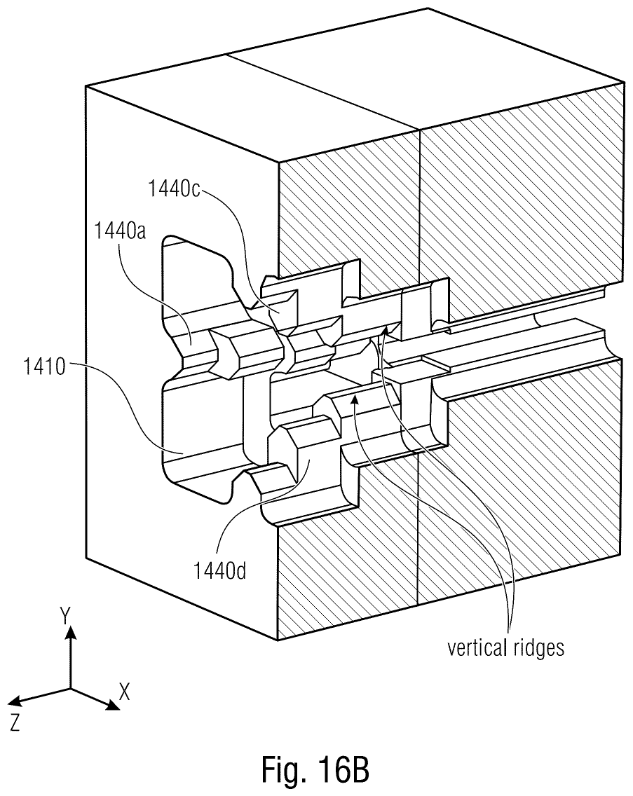

FIG. 16A shows a perspective view of a cross-section of the antenna device 1400 shown in FIG. 14A to 15B, wherein the cross section extends along a vertical plane (e.g., cut planes view onto a plane perpendicular to the X-axis and arranged at: X=0 mm, X=1.5 mm).

The quad-ridged waveguide 1410 is gradually or step-wisely tapered in an axial direction from a radiating aperture 1412 towards the second feed structure 1430b (e.g., in a negative Z-direction in FIG. 16A). For example, a total width and a gap between the ridges are both tapered. For example, a total width in an x-direction, a total width in a y direction, a gap between the ridges 1440a and 1440b in the x direction and a gap between the ridges 1440c and 1440d in the y direction may all be tapered. The step-wise tapering can be seen in FIG. 16A for a first, third and fourth ridge 1440a, c, d. Since the cross-section extends through the third and fourth ridge 1440c, d, the steps are clearly visible in the cross-section.

FIG. 16B shows a perspective view of a cross-section similar to the one depicted in FIG. 16A, wherein the cross section is offset in a positive x-direction. As a result, the (step-wisely tapered) third and fourth ridge 1440c, d are visible in their entirety (i.e. uncut).

FIG. 17A shows a perspective view of a cross-section of the antenna device 1400, wherein the cross section extends along a horizontal plane (e.g., cut planes view onto a plane perpendicular to the Y-axis and arranged at: Y=0.5, Y=−1.5 mm). Since the cross-section extends through a first and second ridge 1440a, b, the steps of the first and second ridges 1440a, b are clearly visible in the cross-section.

FIG. 17B shows perspective view of a cross-section similar to the one depicted in FIG. 17A, wherein the cross section is offset in a negative y-direction. As a result, the E-plane steps 1425 are visible. It should be noted that the E-plane steps 1425 are seen in FIG. 17B only in a bottom half of the antenna device 1400, but as can be seen in FIG. 15B, E-plane steps 1425 may be arranged at the top half as well. Generally, the E-plane steps 1425 may be arranged at at least one of the lateral sides (leading to the lateral arms) and at least one of the bottom and top half.

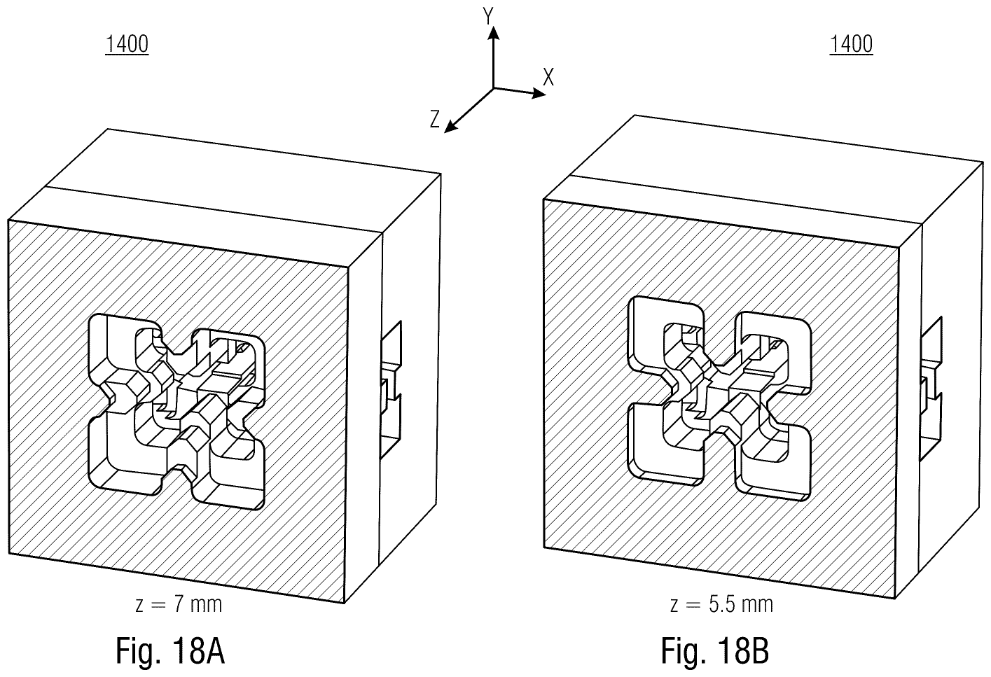

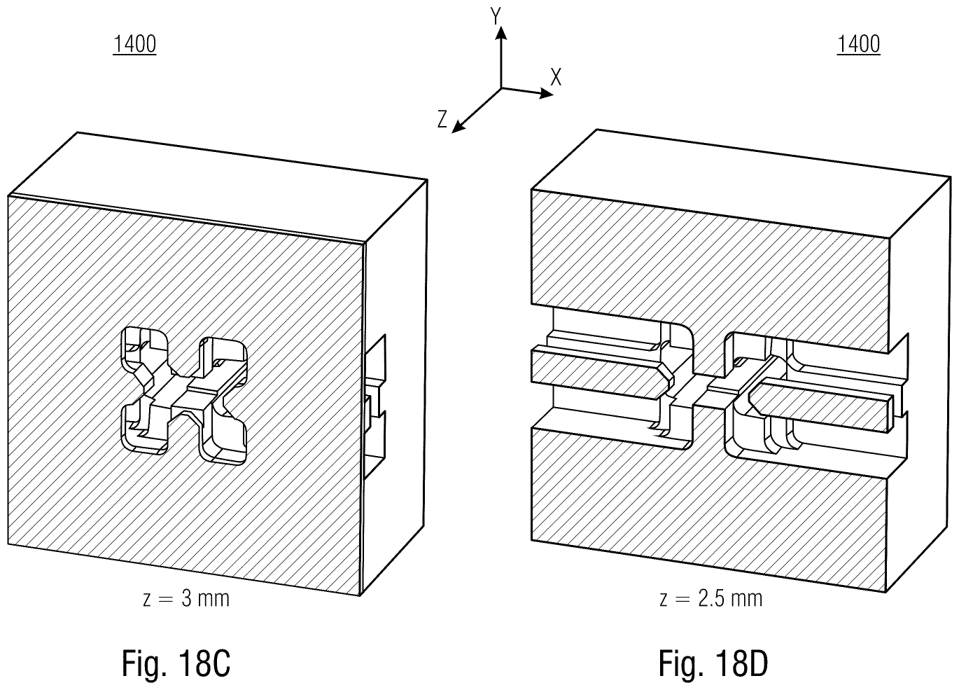

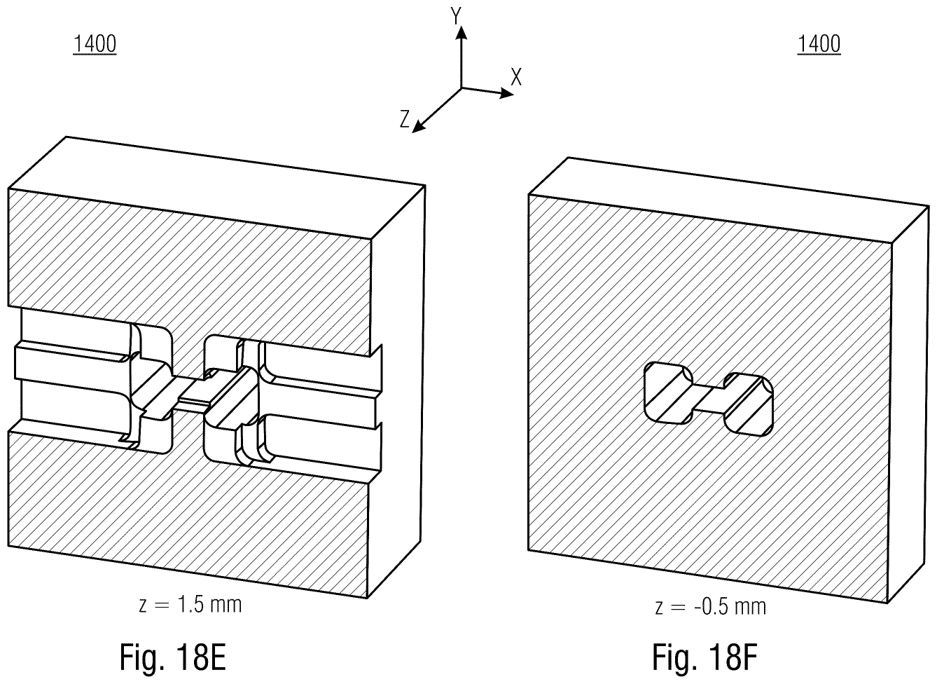

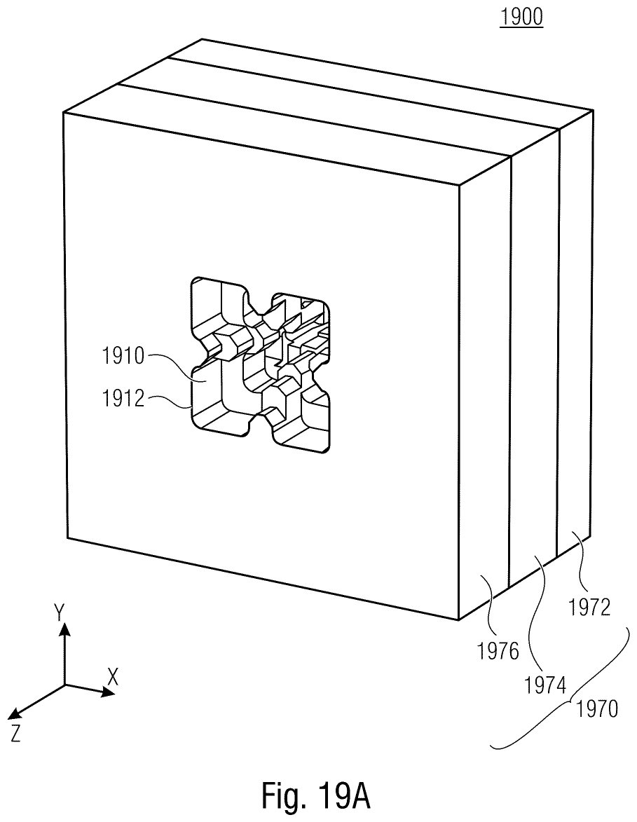

FIGS. 18A to E show perspective views of a cross section of the antenna device 1400, wherein a plane for the cross section is translated to different positions along a z-axis from 7 mm to −0.5 mm. Therefore, a more detailed visualization in cut planes is presented in FIGS. 18A to 18E.

FIG. 18A shows a perspective view of a cross section of the antenna device 1400, wherein the plane for the cross section is positioned at 7 mm.

FIG. 18B shows a perspective view of a cross section of the antenna device 1400, wherein the plane for the cross section is positioned at 5.5 mm.

FIG. 18C shows a perspective view of a cross section of the antenna device 1400, wherein the plane for the cross section is positioned at 3 mm.

FIG. 18D shows a perspective view of a cross section of the antenna device 1400, wherein the plane for the cross section is positioned at 2.5 mm.

FIG. 18E shows a perspective view of a cross section of the antenna device 1400, wherein the plane for the cross section is positioned at 1.5 mm.

FIG. 18F shows a perspective view of a cross section of the antenna device 1400, wherein the plane for the cross section is positioned at −0.5 mm.

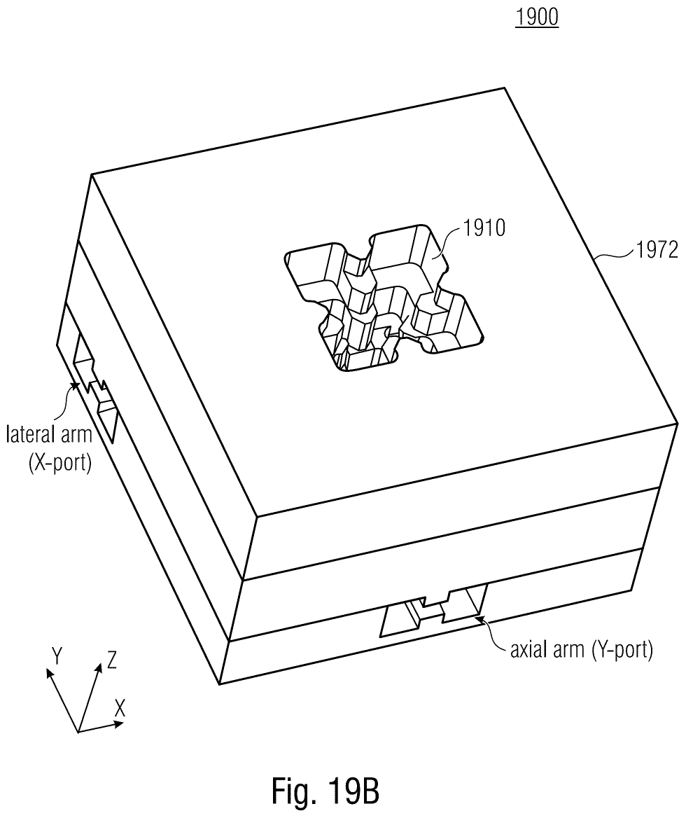

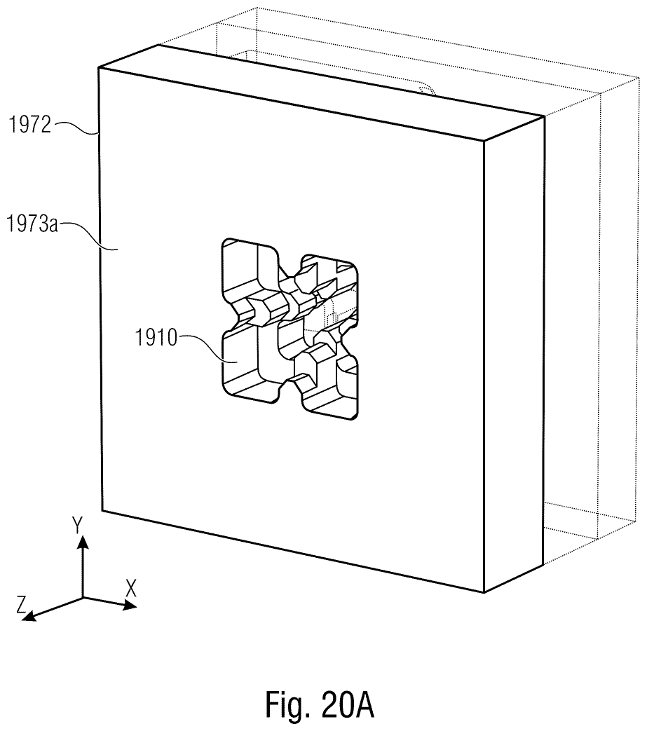

FIGS. 19A to 22B show a perspective view of three housing portions 1972, 1974, 1976 of another embodiment of the antenna device 1900.

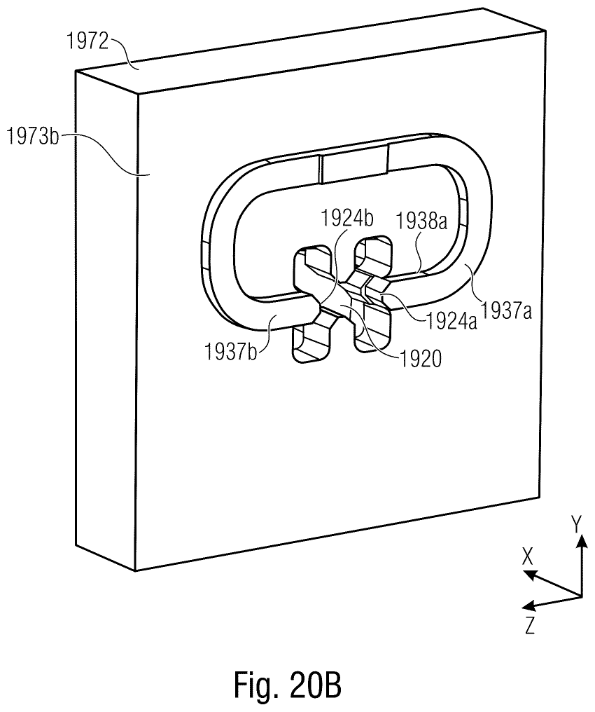

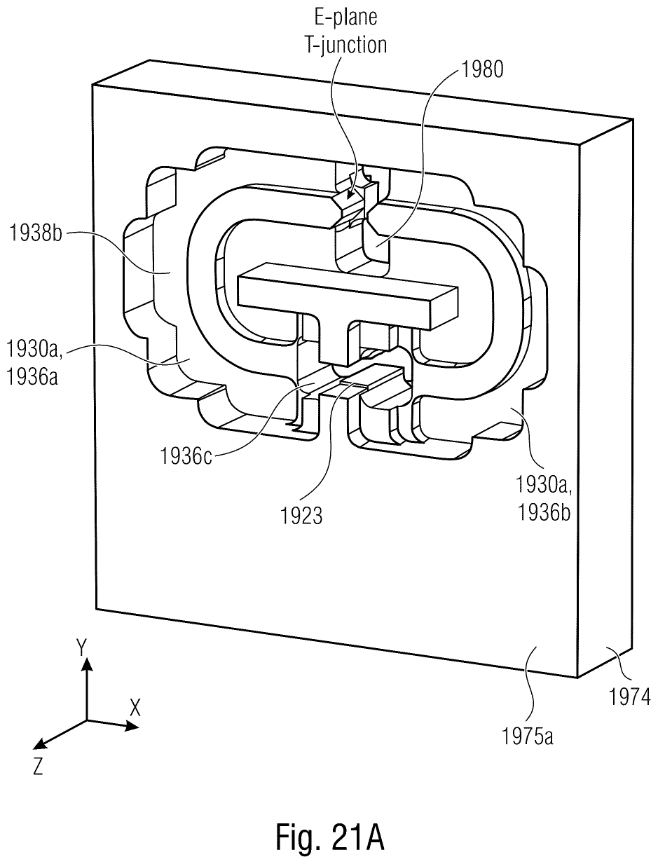

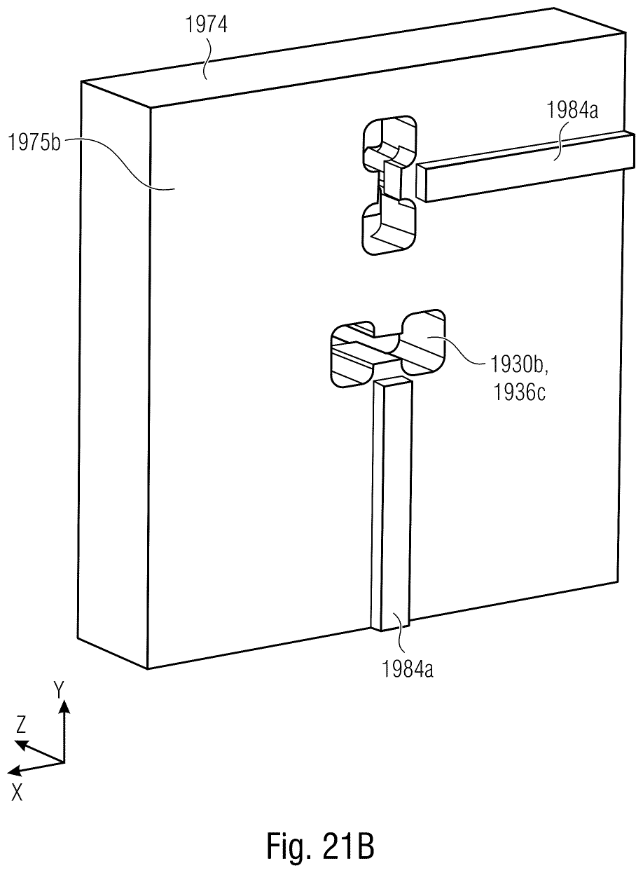

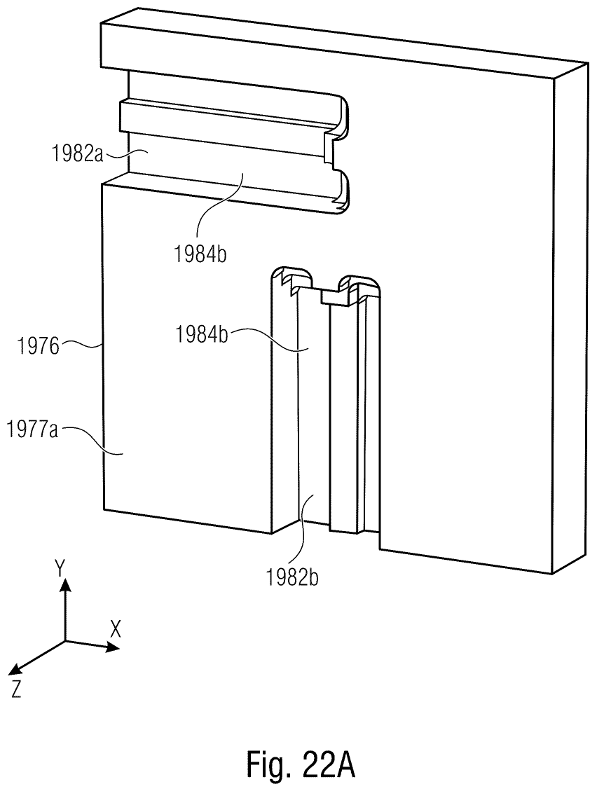

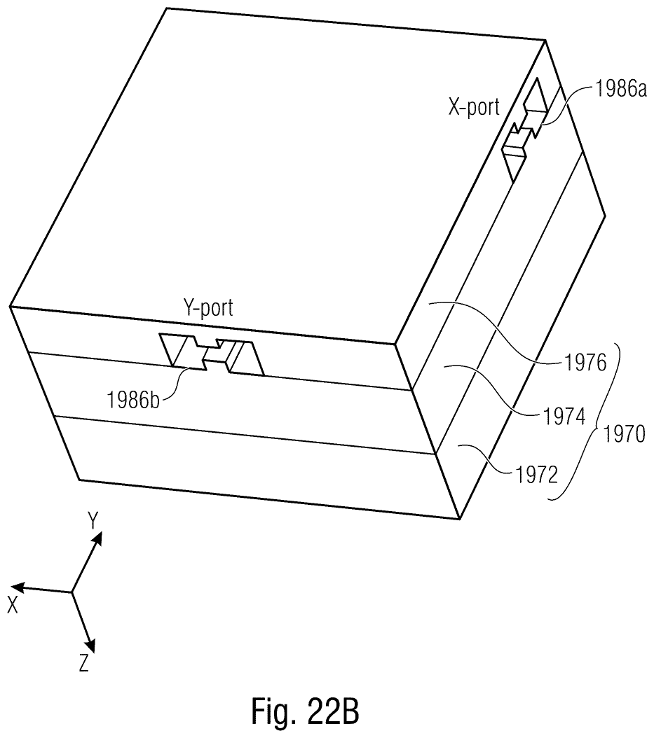

The antenna device 1900 comprises an antenna housing 1970 having three housing portions 1972, 1974, 1976, which may be provided in form of three layers, as depicted in FIGS. 19A to 22B. FIGS. 19A to 22B show solid models of the antenna device 1900 with a feeding network formed in a first housing portion (FIGS. 20A, B), second housing portion (FIGS. 21A, B), and third housing portion (FIGS. 22A, B).

FIG. 19A shows a first perspective view of the antenna device 1900.

FIG. 19B shows a second perspective view of the antenna device 1900.

FIG. 20A shows a perspective view of a first surface 1973a of the first housing portion 1972, wherein the first surface (or main surface) 1973a faces away from the second housing portion 1974.

FIG. 20B shows a perspective view of a second surface 1973b (or main surface) (or inner surface) of the first housing portion 1972, wherein the second surface 1973b faces towards the second housing portion 1974.

FIG. 21A shows a perspective view of a first surface (or main surface) 1975a of the second housing portion 1974, wherein the first surface 1975a faces towards the first housing portion 1972.

FIG. 21B shows a perspective view of a second surface (or main surface) 1975b of the second housing portion 1974, wherein the second surface 1975b faces towards the third housing portion 1976.

FIG. 22A shows a perspective view of a first surface (or main surface) 1977a of the third housing portion 1976, wherein the first surface 1977a faces towards the second housing portion 1974.

FIG. 22B shows a perspective view of a second surface (or main surface) 1977b of the third housing portion 1976, wherein the second surface 1977b faces away from the second housing portion 1974.

The antenna housing 1970 comprises a first housing portion 1972 (e.g. a first layer), a second housing portion 1974 (e.g. a second layer) and a third housing portion 1976 (e.g. a third layer). The housing portions may be arranged in a stack of layers in such a way that the second housing portion 1974 is located between the first and third housing portions 1972, 1976. An antenna device comprising three (or more) housings (or housing portions) is exemplarily described with reference to the antenna device 1900 depicted in FIG. 19A. It should be noted that any other antenna device described herein may also comprise (or be separated into) three or more housing portions.

A quad-ridged waveguide 1910 with a radiating aperture 1912 is formed in the first housing portion 1972 (see FIGS. 19A to 20A). To this end, the quad-ridged waveguide 1910 may be at least one of milled and micromachined in the first housing portion 1972. The quad-ridged waveguide 1910 shown in FIG. 19A is gradually or step-wisely tapered in a direction from the first surface 1973a of the first housing portion 1972 towards the second surface 1973b (or inner surface) of the first housing portion 1972. Alternatively, the quad-ridged waveguide 1910 may comprise a different tapering or no tapering.

The first housing portion 1972 comprises on its second surface 1973b a first portion 1938a (e.g. ridges 1937a, b, or one or more recesses with one or more ridges) of waveguide structures that extend between lateral ports 1924a, b of the orthomode transducer 1920 and a T-type waveguide joint 1980.

The second housing portion 1974 comprises, on its first side (e.g., on the first surface 1975a of the second housing portion 1974), a second portion 1938b (e.g. one or more recesses with one or more ridges) of the waveguide structures that extend between the lateral ports 1924a, b of the orthomode transducer 1920 and the T-type waveguide joint 1980.

At least a part of the first and second portions 1938a, of the waveguide structures that extend between lateral ports 1924a, b of the orthomode transducer 1920 and a T-type waveguide joint 1980 may form at least partially first and second double-ridged waveguides 1936a, b which can utilize several waveguide bends (e.g. right angle or 90° bends in a plane parallel to waveguide's broad wall, i.e. magnetic field- or H-plane bends). The H-plane bends may incorporate several steps that are rounded/flared for the ease of manufacturing (e.g., milling). The H-plane bends provide ease of routing of the double-ridged waveguides 1936a, b and help to reduce lateral dimensions of the feeding network. The first and second double-ridged waveguides 1936a, b form at least a part of a first feed structure 1930a. For example, boundaries of the first and second double-ridged waveguides may be formed by the structuring of the second surface of the first housing portion and of the first surface of the second housing portion.

The second housing portion 1974 further comprises, on its second side (e.g., on the second surface 1975b of the second housing portion 1974), a first portion 1984a (e.g. a ridge, or a recess with a ridge) of a waveguide structure that extends from the T-type waveguide joint 1980 to a first external connection 1986a and, optionally (as seen in FIGS. 21B and 22A), also a first portion 1984a (e.g. a ridge or a recess with a ridge) of a waveguide structure that extends from the axial port 1923 of the orthomode transducer 1920 to a second external connection 1984b.

The third housing 1976 comprises a second portion 1984b (e.g. a recess with a ridge) of the waveguide structure that extends from the T-type waveguide joint 1980 to the first external connection 1986a (e.g. a first blind-mating waveguide connection) and a (second) portion 1984b (e.g. a recess with a ridge) of the waveguide structure that extends form the axial port 1923 of the orthomode transducer 1920 to the second external connection 1986b (e.g. a second blind-mating waveguide connection).

The first double-ridged waveguide 1936a and the second double-ridged waveguide 1936b are, at least partially (or, optionally, fully), formed (e.g. milled and/or micromachined) in the second housing portion 1974 or at a transition between the first housing portion 1792 and the second housing portion 1974. In other words, the second housing portion 1972 forms a part (e.g. a wall, e.g. a cap, e.g. a cover) of the first and second double-ridged waveguides 1936a, b. To this end, a first ridge 1937a of the first double-ridged waveguide 1936a and a first ridge 1937b of the second double-ridged waveguide 1936b are formed at the first housing portion 1972 (see FIG. 20B). A remaining portion (e.g., second portion 1938b) of the first and second double-ridged waveguides 1936a, b is formed in the second housing portion 1974 (see FIG. 21A). Alternatively, the first and second double-ridged waveguides 1936a, b may be formed entirely in one of the first and second housing portions 1972, 1074 or at a different transition between the first and second housing portions 1972, 1974.

A third double-ridged waveguide 1936c is formed (e.g., milled and/or micromachined) in the second housing portion 1974 (see FIGS. 21A, B). The third double-ridged waveguide 1936c forms at least a part of a second feed structure 1930b.

The antenna device 1900 has two ports (or three ports, when counting the lateral ports as two ports) for coupling to the first and second feed structures, e.g. two lateral ports 1924a, b (see FIG. 20B) for the horizontal polarization and an axial port 1923 (see FIG. 21A) for the vertical polarization. For OMT operation, the lateral arms are fed out-of-phase (λ/2+2πn), so a specific waveguide tee may be used (for connecting the two lateral arms of the OMT with a common double-ridged waveguide) for lossless combining of signals of the lateral arms to the common port. An E-plane T-junction naturally provides 180° phase shift at output waveguides, hence, the differential signals are combined. Vice versa, due to reciprocity, excitation of the horizontal polarization in OMT needs out-of-phase signals in the feeding lateral arms. To that end, E-plane T-junction 1980 splits a signal of the common port into two out-of-phase signals that are equal in magnitudes.

The antenna device 1900 comprises a combiner/splitter structure 1980 (e.g. a T-junction or T-type waveguide joint; e.g. an E-plane T-junction) that is formed (e.g., milled and/or micromachined) in the second housing portion 1974 (and optionally also includes structures in the first housing portion 1972 and/or on the third housing portion).

The tee (e.g., combiner/splitter structure 1980) is formed (e.g., milled) inside the second housing portion 1974 (FIG. 21A, B) which also serves as a cap of the first and second output double-ridged waveguides 1982a, b, milled in in the third housing portion 1976 (FIG. 22A, B).

Hence, a very low-profile antenna (e.g., antenna device 1900) and waveguide feeding network are obtained as antenna thickness is low (e.g., only between 10.0 mm and 15.0 mm, such as 13.5 mm). For example, commercial quad-ridged horn antennas or OMTs are typically larger than 30 mm in height each. The developed waveguide distribution network benefits from 3 arms only in the Boifot OMT instead of 4 arms in the conventional turnstile OMT.

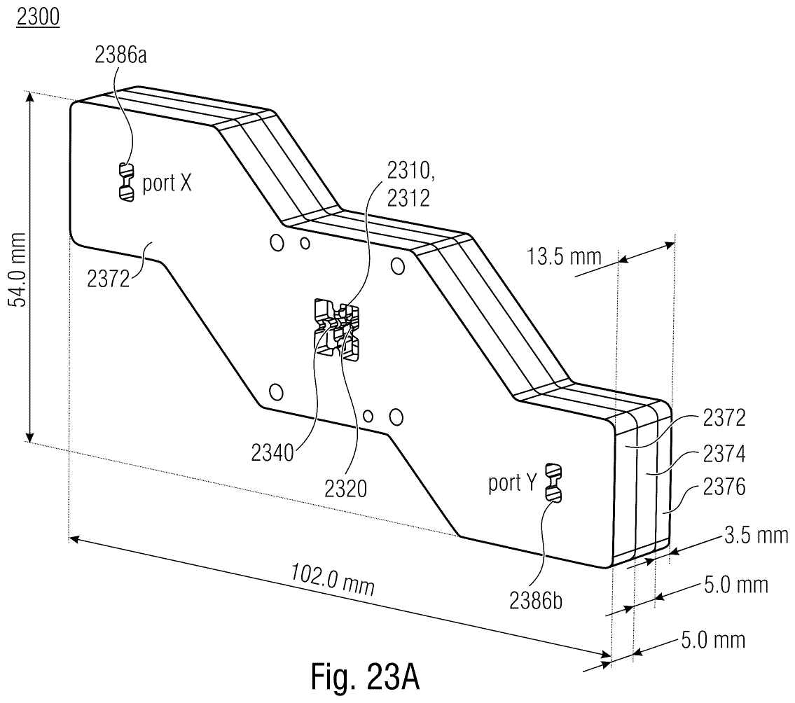

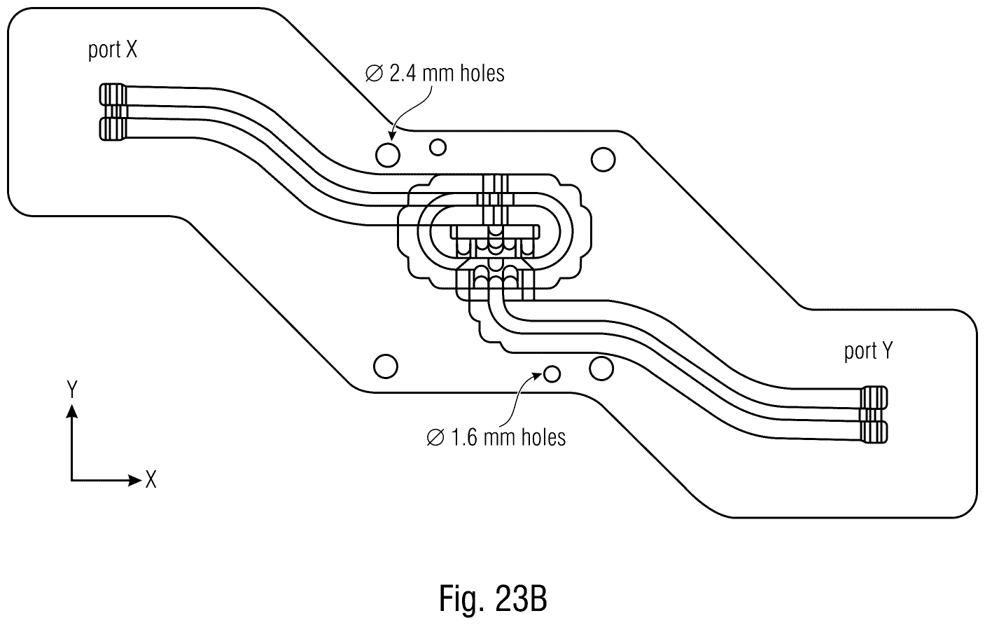

FIG. 23A shows a further embodiment of an antenna device 2300. The antenna device 2300 comprises a first housing (or housing portion) with a thickness of, for example, 5.0 mm, a second housing (or housing portion) with a thickness of, for example, 5.0 mm, and a third housing (or housing portion) with a thickness of, for example, 3.5 mm. Therefore the antenna device 2300 has a total thickness of, for example, 13.5 mm. The three housing portions have at least essentially a similar shape (i.e. in a direction perpendicular to its corresponding thickness). In other words, the three housing portions are at least essentially congruent when stacked on top of each other. The shape of the three housing portions in FIG. 23A has a length of, for example, 102.0 mm and a width of, for example, 54.0 mm.

The antenna device 2300 of FIG. 23A and the antenna device 1900 of FIG. 19A have similar (or same) central features (e.g. quad-ridged waveguide, OMT, first and second feed structures) and differ essentially in a shape of the antenna device and a routing of the waveguide structures (feeding waveguides) that extends from the axial port and lateral ports of the orthomode transducer to a first and second external connections 2386a, b (e.g. comprising or consisting of first and second output double-ridged waveguides 2382a, b; e.g., axial arm (Y) routing and lateral arm (X) routing). FIG. 23A shows first and second external connections 2386a, b (e.g. Port X, Y), which form openings of a first housing portion 2372. The openings of the first and second external connections 2386a, b may be arranged in a same plane as a radiating aperture 2312 of the quad-ridged waveguide 2310. Furthermore, the waveguide structures at the first and second external connections 2386a, b may extend parallel to an extension direction of the quad-ridged waveguide 2310.

At least one of the first and second external connections 2386a, b may be a blind-mating waveguide connection. To this end, at least one of the first and second external connections 2386a, b may comprise self-alignment features (e.g., one or more conical recesses and/or protrusions).

FIG. 23B shows a frontal view of the antenna device 2300 of FIG. 23A. FIG. 23B further shows holes around the quad-ridged waveguide of the antenna device 2300. The holes may be used to mechanically connect the housing portions to each other (e.g., using screws). Alternatively, the holes may be used for mating (e.g., blind mating) the antenna device 2300 to another device (e.g., a test socket of an automated test equipment).

FIG. 23B also indicates hollow structures (e.g., double-ridged waveguides, quad-ridged waveguides, and OMT) inside the antenna device 2300 in form of a projection onto a plane perpendicular to an extension direction of the quad-ridged waveguide (i.e., projection onto the drawing plane).

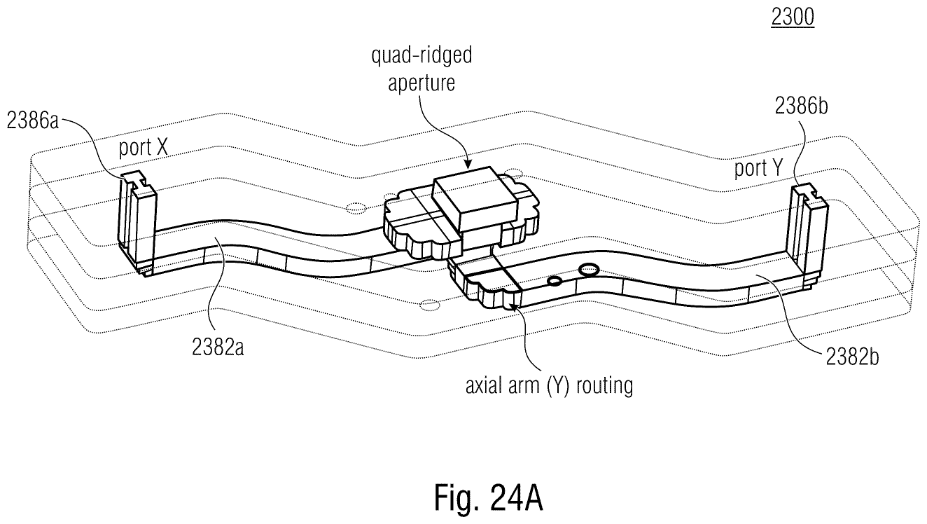

FIG. 24A shows a perspective view of the hollow structures inside the (semi-transparently indicated) antenna device 2300. The hollow structures are only illustrated schematically and do not show all details (e.g., the ridges of the quad-ridged waveguide).

FIG. 24B shows a perspective view of the antenna device 2300 from essentially an opposite view point compared to FIG. 24A.

As can be seen in FIGS. 24A, B, the first output double-ridged waveguide 2382a connects a first external connection 2386a (e.g., Port X) with a T-type waveguide joint 2380 (and by extension with two lateral ports of the OMT 2320) and the second double-ridged waveguide 2382b connects a second external connection 2386b (e.g., Port Y) with an axial port of the OMT 2320. The first and second output double-ridged waveguides 2382a, b have a lateral extension, which is formed by first and second portions in second and third housing portions 2374, 2374, similarly as first and second portions 1984a, b described above with reference to antenna device 1900. The first and second output double-ridged waveguides 2382a, b also have an axial extension (reaching the first and second external connections 2386a, b, respectively) through the second housing portion 2374 and a first housing portion 2372.

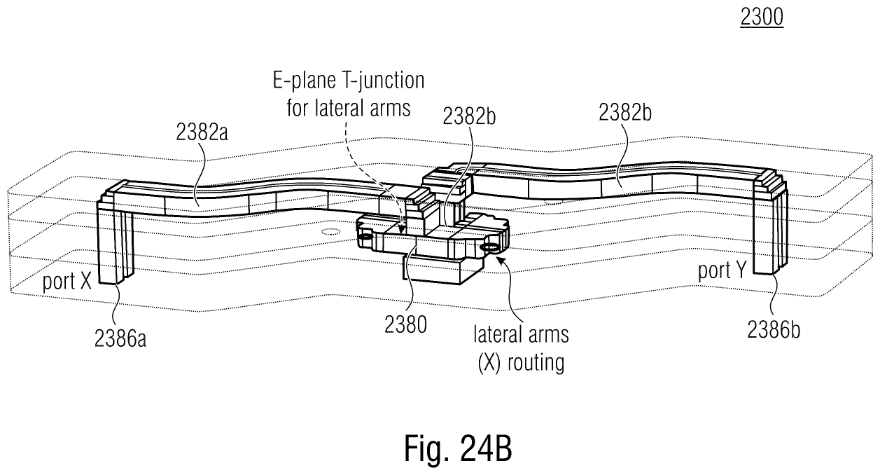

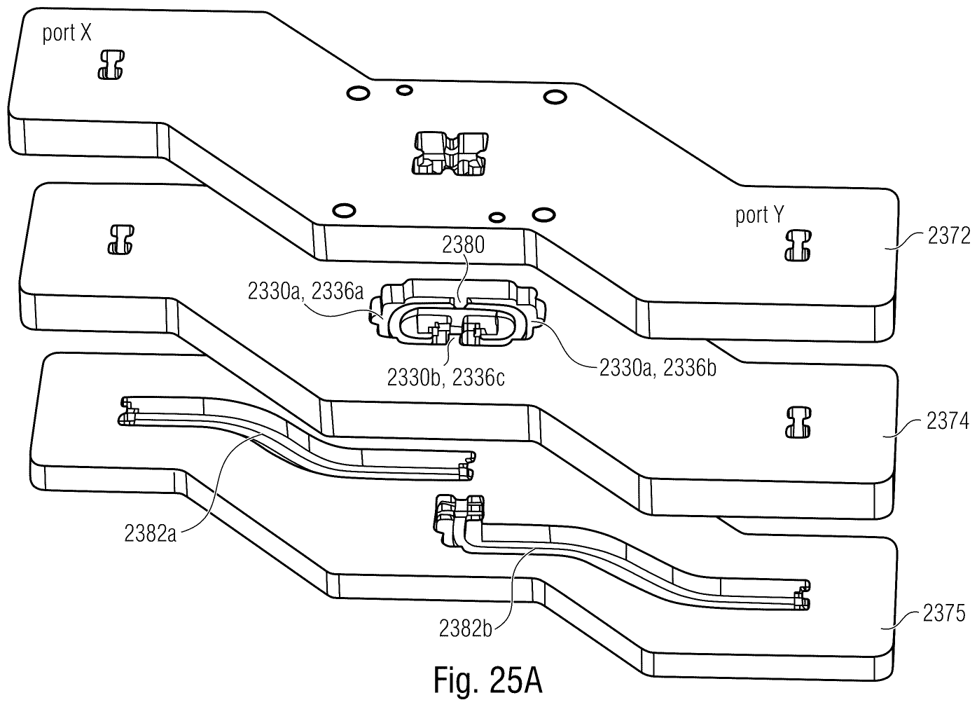

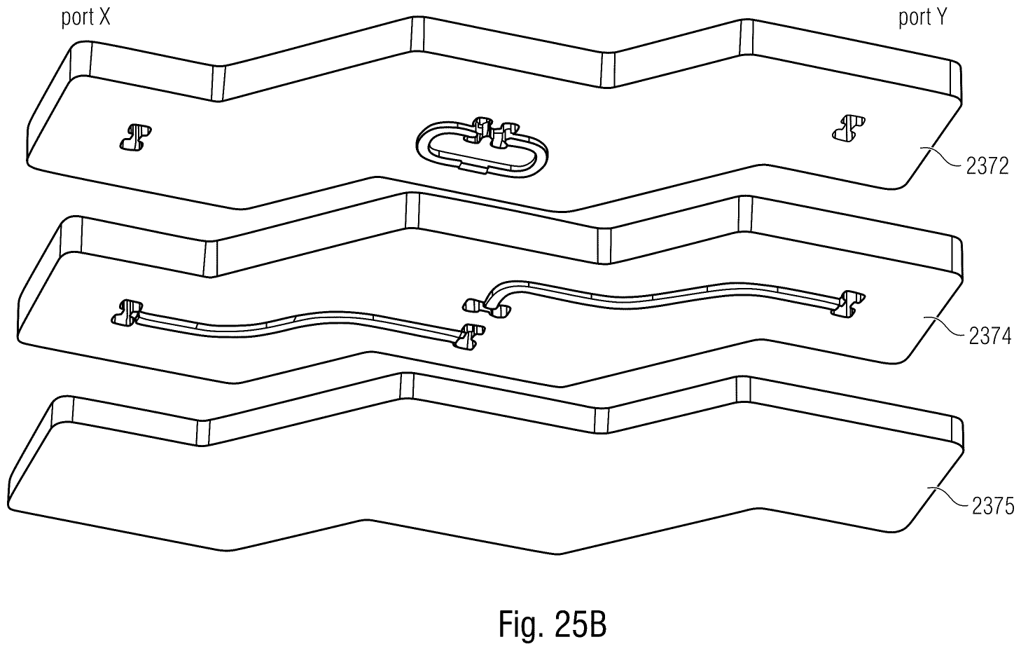

FIG. 25A shows a exploded view of the antenna device 2300 with a view of top surfaces of each housing portion 2372, 2374, 2376.

FIG. 25A shows an exploded view of the antenna device 2300 with a view of bottom surfaces of each housing portion 2372, 2374, 2376.

The first and second housing portions 2374 have congruent openings in order to form (at least a part of) the axial extension of the first and second output double-ridged waveguides 2382a, b. The openings may have a double-ridged shape as shown in FIG. 25A, B.

### 2.3 ATE Measurement Antenna Design

Considering an automated test equipment (ATE) handler antenna application, a low-profile antenna made in “sliced” housings (e.g., first, second, and third housing portions 2372, 2374, 2376) may be suitable. Therefore, lateral arms of the quad-ridged Boifot OMT are routed in XY-plane (e.g., perpendicular to an extension direction of the quad-ridged waveguide) and parallel to housing slices (e.g., parallel to an extension direction of layers of the antenna housing) (see FIGS. 24A, B). It can be observed that the lateral ports (e.g., lateral ports 1924a, b or similar ports in other embodiments) are fed with λ/2 phase shift (FIG. 23b) that is advantageous for OMT operation. Therefore, the lateral ports (or signals from the lateral ports) are combined with E-plane T-junction (FIGS. 25A, B), because such a junction provides differential outputs (or differentially combines incoming signals). The rest of waveguide feeding network may use E/H-plane waveguide bends/turns for the desired disposition of output ports (e.g., blind-mating interconnects).

For the wideband radiation feature the antenna uses stepped ridges 2340 (see FIG. 23A). This allows a low-profile aperture to be milled, for example, in 5 mm thick housing or housing portions (see FIGS. 23A and housing portion 2372 in FIGS. 25A, B). The second housing or housing portion 2374 contains an axial arm waveguide (e.g., a third double-ridged waveguide 2336c; e.g., a second feed structure 2330b). The second housing portion 2374 contains lateral arms waveguides (e.g., first and second double-ridged waveguides 2336a, b, e.g., a first feed structure 2330a) and an E-plane T-junction 2380 for differential combining, whereas the third housing portion 2376 comprises a waveguide feeding network (e.g., first and second output double-ridged waveguides 2382a, b) for X & Y double-ridged waveguide interfaces (see FIGS. 25A, B). Inner edges of the housing portions 2372, 2374, 2376 have, for example, been rounded for Ø1 mm endmill tooling. However, endmill tooling with other diameters (e.g., 0.2 mm to 2.0 mm) may be used instead. According to double-ridged waveguide simulations, a larger diameter of inner rounding decreases waveguide performance. However, Ø1 mm tool for fine milling seems reasonable.

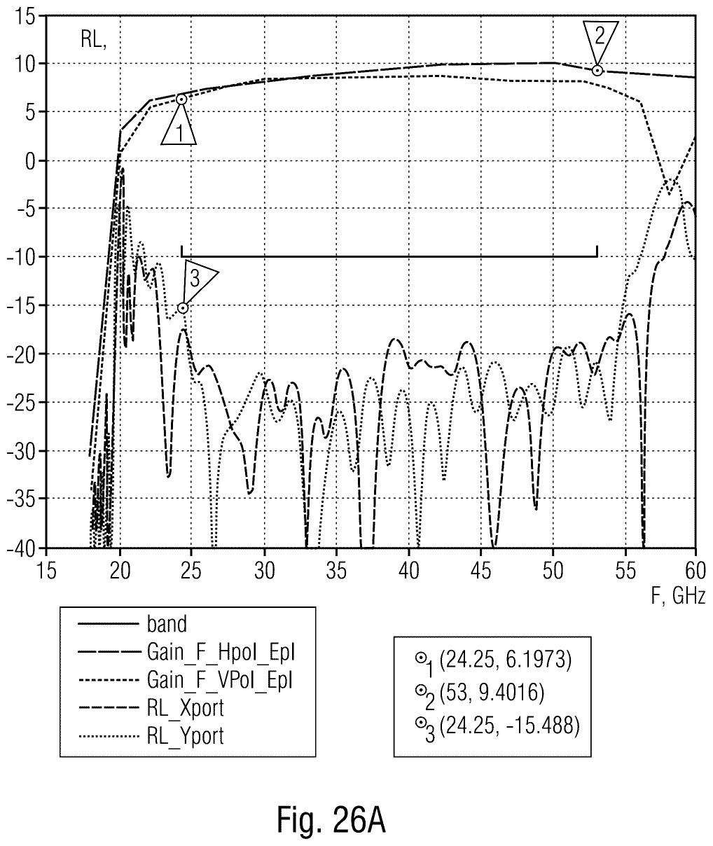

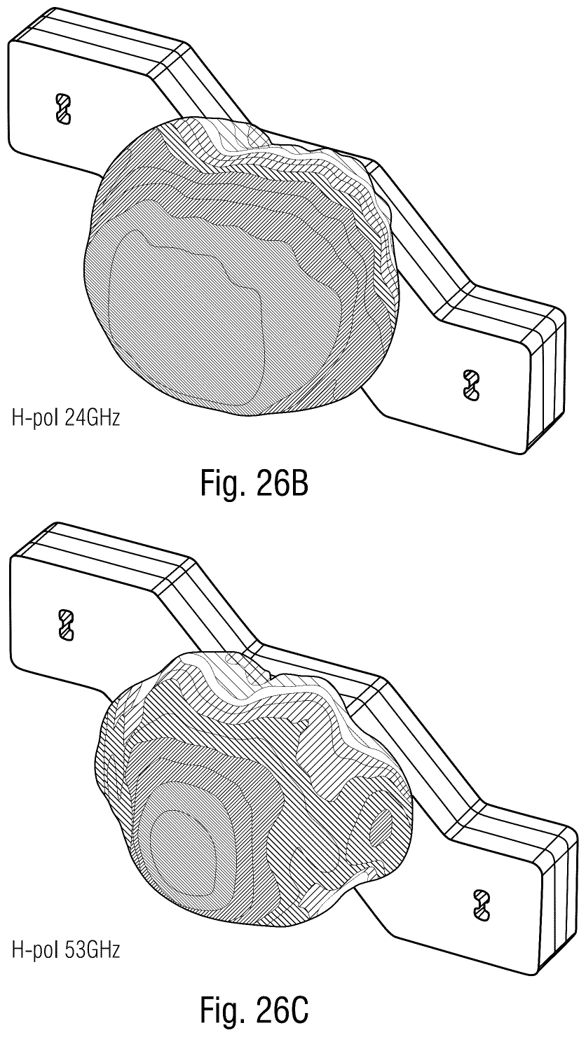

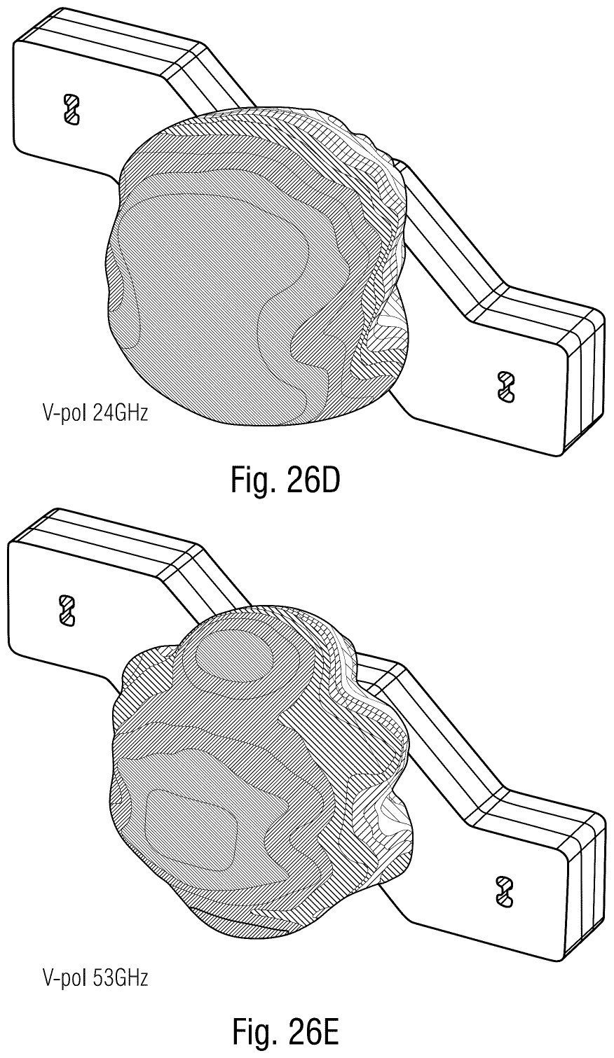

FIG. 26A shows a graphic representation of a simulation result for reflection coefficients (S₁₁, S₂₂) and antenna gains of an antenna device such as antenna device 2300.

Simulated RL & antenna boresight gain performance depicted in FIG. 26A shows a 23.2-54.6 GHz operational band with >15 dB RL. Cross-port isolation is >50 dB over the band (or cross-port-transmission/cross-port talk lays below −50 dB over the band).

FIG. 26B shows a simulation result for far-field radiation pattern of a horizontal polarization at 24 GHz.

FIG. 26C shows a simulation result for far-field radiation pattern of a horizontal polarization at 53 GHz.

FIG. 26D shows a simulation result for far-field radiation pattern of a vertical polarization at 24 GHz.

FIG. 26E shows a simulation result for far-field radiation pattern of a vertical polarization at 53 GHz.

As can be seen in FIGS. 26B to E, far-field patterns are symmetrical and stable over the 24-53 GHz band for both polarizations.

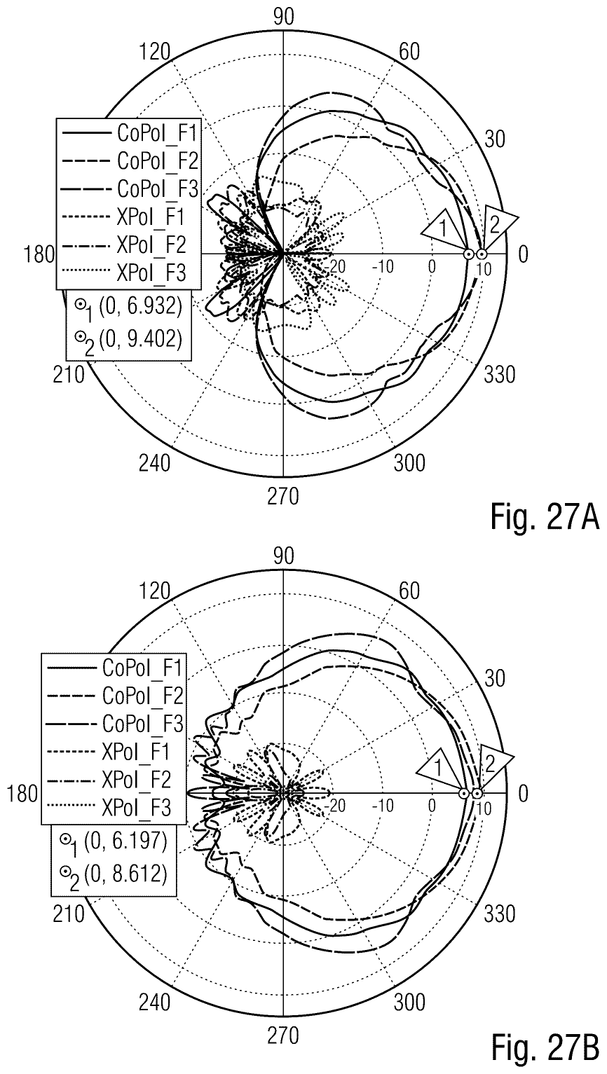

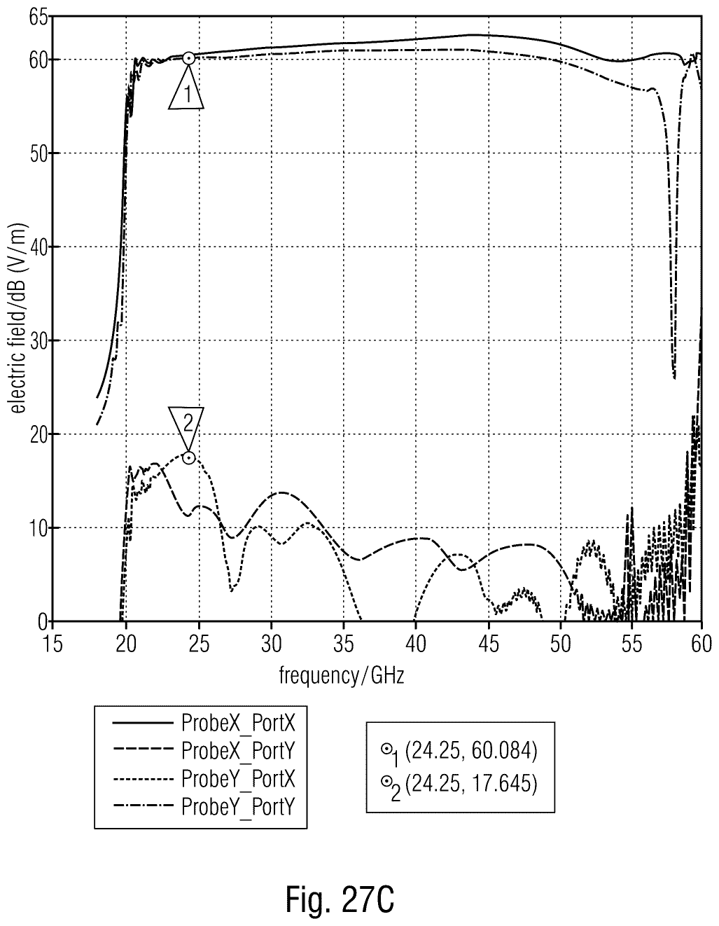

FIG. 27A shows a graphic representation of a simulation result for a far-field radiation pattern cutplane for horizontal polarization at frequencies of F₁=24 GHz, F₂=37 GHz, F₃=53 GHz, in polar coordinates.

FIG. 27B shows a graphic representation of a simulation result for a far-field radiation pattern cutplane for vertical polarization at frequencies of F₁=24 GHz, F₂=37 GHz, F₃=53 GHz, in polar coordinates.

For horizontal and vertical polarizations, antenna gain varies in a 6.9-10.2/6.2-8.7 dBi range respectively, whereas cross-polarization discrimination in far-field is >25 dB in the boresight direction (see FIGS. 27A, B).

FIG. 27C shows a graphic representation of a simulation result for E-field components magnitudes over frequency of a virtual orthogonal probes pair (ProbeX, ProbeY) placed 11 mm above the antenna aperture.

When the virtual E-field probe pair is placed 11 mm above the antenna aperture, it registers, by simulations, >40 dB diversity between orthogonal E-field components in near-field.

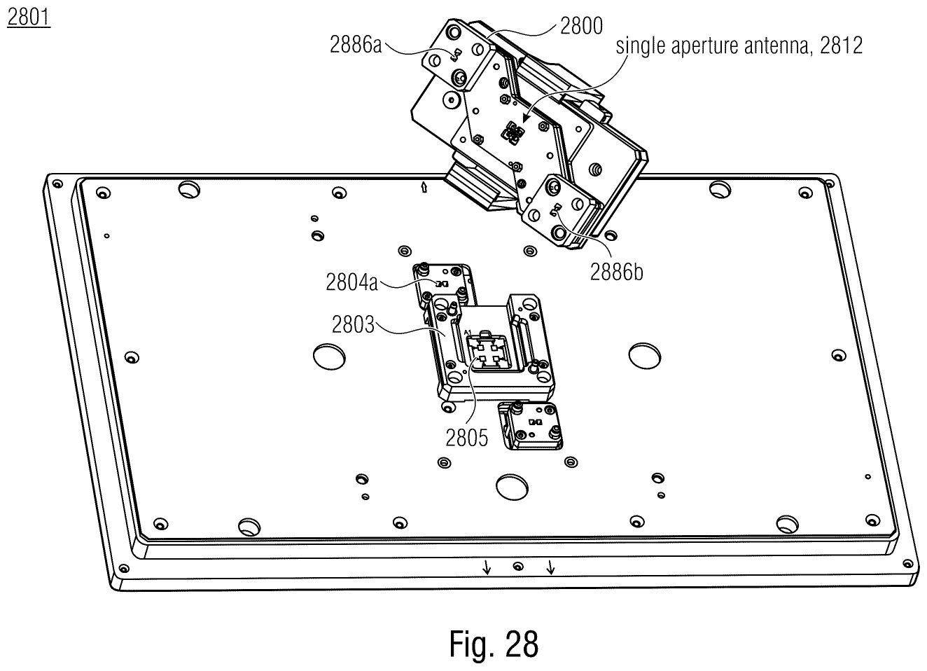

A possible application of the antenna device as described herein is an automated test equipment (ATE), as exemplarily depicted in FIGS. 28 to 30.

FIG. 28 shows an embodiment of an ATE 2801 with an antenna device 2800 without a cover.

The ATE 2801 is configured to test a device under test using the antenna device 2800 (which essentially corresponds to antenna device 2300). To this end, the ATE 2801 may comprise a device under test socket 2803 (e.g., an electrical socket) and one or more high frequency connectors (e.g. waveguide connections) 2804a, b. The high frequency connectors 2804a, b may be located at the end of waveguides. The waveguides of the high frequency connectors 2804a, b may be double-ridged waveguides, e.g., double-ridged waveguides that reach up to the high frequency connectors (e.g. waveguide connections) 2804a, b. The high frequency connectors (e.g. waveguide connections) 2804a, b may be configured to match first and second external connections 2886a, b (e.g., match in at least one of size, orientation and cross-section).

At least one of the first and second external connections 2886a, b and the high frequency connectors 2804a, b may be configured for blind mating. For example, the first and second external connections 2886a, b may have (e.g., in its surrounding area) conical protrusions and the high frequency connectors (e.g. waveguide connections) 2804a, b may have (e.g., in its surrounding area) conical openings configured to receive the conical protrusions (or vice versa). The high frequency connectors (e.g. waveguide connections) 2804a, b may be configured for establishing a high frequency connection with the antenna device (e.g., via the first and second external connections 2886a, b).

The high frequency connectors (e.g. waveguide connections) 2804a, b may be arranged beside the test socket 2803 as depicted in FIG. 28. An arrangement of the first and second external connections 2886a, b and a radiating aperture 2812 may be arranged in a first geometrical relationship that matches a second geometrical relationship of the high frequency connectors 2804a, b and the test socket 2803. As a result, the antenna device 2801 can be placed on top of the test socket 2803 and the high frequency connectors 2804a, b can be placed in a way to align (e.g., mate) with the radiating aperture 2812 and the first and second external connections 2886a, b.

The test socket 2803 may be configured to couple to a device 2805 to be tested (e.g., an antenna in package or an antenna-in-package device).

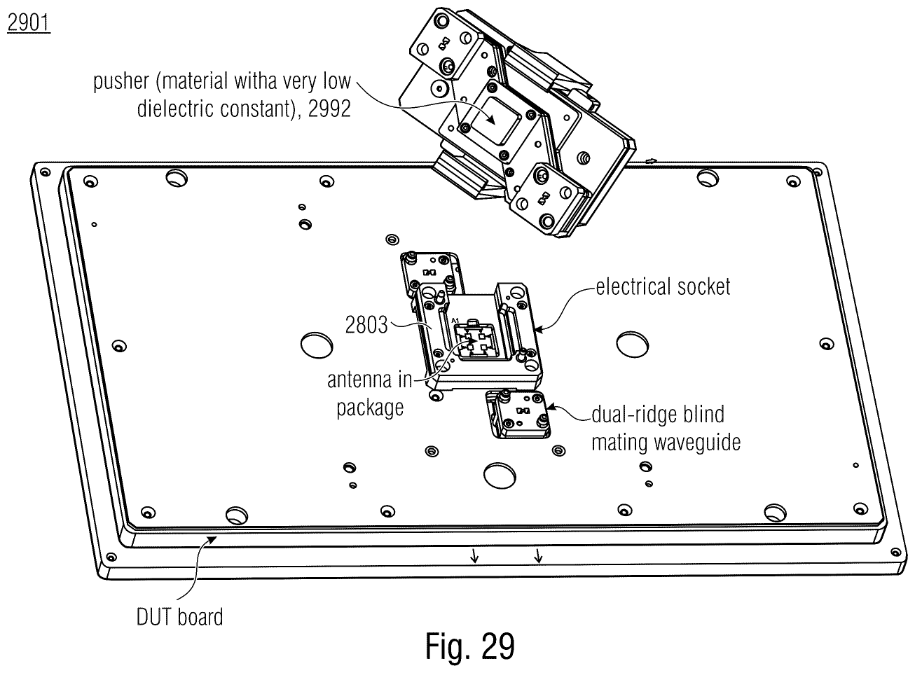

FIG. 29 shows another embodiment which is similar to the embodiment of FIG. 28, wherein an antenna device 2900 further comprises, in addition to the features of the antenna device 2800, a cover 2992 (e.g., pusher). The antenna device 2900 may comprise the cover 2992 as part of a system comprising the ATE 2901 as shown in FIG. 29, or the antenna device 2900 alone may comprise the cover 2992.

The cover is, for example, intended to push the device. Its size is determined, for example, by the DUT size. The size may possibly (but not necessarily) deviate from the antenna aperture size. In other words, it is advantageous that the cover (i.e. pusher) is defined by the DUT size. The cover 2992 may, in some embodiments, cover the radiating aperture (not depicted in FIG. 29). The cover 2992 may be removable and attachable (e.g., by screws or a latching mechanism). The cover 2992 may be (at least partially) radio transparent (or electromagnetically transparent). As a result, the cover does not (or largely does not) block transmission of electromagnetic waves between the radiating aperture and the test socket 2903 (or a device coupled to the test socket 2803).

The cover 2892 forms a physical barrier between the radiating aperture 2812 and the test socket 2803 (and/or the device 2805 to be tested coupled thereto) and can reduce or avoid mechanical damage caused to the device 2805 to be tested coupled to the test socket 2803. The cover 2892 may comprise or consist of a polymer (e.g., plastic). Polymer has increased deformability (e.g., compared to metal), which further increases protection of the device 2805 to be tested. Polymers commonly have high electrical resistances and therefore also increase protection from unintended short-circuiting the device 2805 to be tested.

The device 2805 to be tested may be fixed to the test socket 2803 by the cover 2892 applying pressure on the device 2805 to be tested. Alternatively or additionally, the test socket 2803 (and/or the antenna device 2800) may have attachment elements (e.g., at least one of a clamp, a pusher, and a suction cup). The cover 2892 allows bringing the radiating aperture 2812 in close proximity of the device 2805 to be tested (e.g., in a range of 10 mm to 20 mm or 40 mm), which improves measurements of a near-field of the device 2805 to be tested (e.g., within two wavelengths or more of an electrical field to be tested).

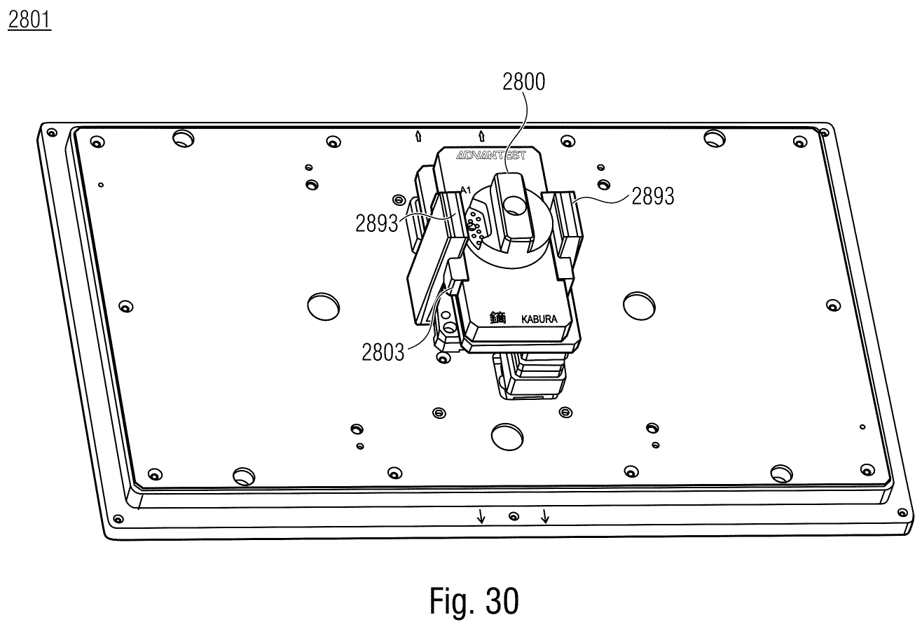

FIG. 30 shows the antenna device 2800 of FIGS. 28, 29 mated to the test socket 2803 and the high frequency connectors 2804a, b.

The antenna device 2800 may comprise clamps 2893 configured to engage an engagement element (e.g., an indentation of or below the test socket 2803). Alternatively, however, the clamps may be fixed to the test socket or to the load board carrying the test socket, and engage with the antenna device. The clamps 2893 are configured to attach the antenna device 2800 to the socket 2803 (or any other part of the ATE 2801 such as the high frequency connectors 2804a, b). The clamps 2893 may be biased into an engagement position. The clamps 2893 may, for example, have slanted surfaces that move the clamps 2893 into a disengagement position when pushed against the test socket 2803. As a result, the antenna device 2800 can be coupled to the test socket 2803 by pushing the antenna device 2800 onto the test socket 2803. Alternatively or additionally, the clamps 2893 may have handles or a built in actuator that allows switching between the engagement position and the disengagement position.

The clamps 2803 may be configured to hold the high frequency connectors 2804a, b and the first and second external connections 2886a, b in a mating arrangement. Alternatively or additionally, the high frequency connectors 2804a, b and/or the first and second external connections 2886a, b may comprise attachment features for attaching the first and second external connections 2886a, b to the high frequency connectors 2804a, b.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### REFERENCES

[1]. A. Boifot, E. Lier, T. Schaug-Pettersen, “Simple and broadband orthomode transducer,” in IEE Proceedings, vol. 137, no. 6, December 1990
[2]. A. Gonzalez, Sh. Asayama, “Double-ridged waveguide orthomode transducer (OMT) for the 67-116-GHz band,” in J Infrated Milli Terahz Waves, pp. 723-737, 2018
[3]. M. Abdelaal, Sh. Shams, M. Moharram, M. Elsaadany and A. Kishk, “Compact full band OMT based on dual-mode double-ridge waveguide,” in IEEE Trans. on Micr. Th. and. Tech., 2018
[4]. Sh. Asayama, T. Nakajima, “Development of a smooth taper double-ridge waveguide orthomode transducer for a new 100 GHz band Z-machine receiver for the NRO 45-m radio telescope,” in Publications of the astronomical society of the Pacific, 2013
[5]. E. Menargues, S. Capdevila, T. Debogovic, A. Dimitriades, L. Simon, M. Garcias-Vigueras, J. Mosig, A. Skrivervik and E. Rijk, “Four-port broadband orthomode transducer enabling arbitrary interelement spacing,” in IEEE Trans. on Micr. Th. and Tech., 2018
[6]. T. Zhang, Z. Yan, L. Chen and F. Fan, “Design of broadband orthomode transducer based on double-ridged waveguide,” in ICMMT Proceedings, 2010.
[7]. L. Shu, J. Noh, B. Enkhbayar, J. Bang and B. Ahn, “Design of E-band Boifot ortho-mode transducer,” in J. of KIIT, vol. 14, no. 8, pp. 1-9, August 2016

1. An antenna device, the antenna device comprising:
a quad-ridged waveguide,
an orthomode transducer, OMT, and
at least two feed structures;
wherein an open end of the quad-ridged waveguide is configured to act as a radiating aperture; and
wherein the orthomode transducer, OMT, is configured to couple the quad-ridged waveguide to the at least two feed structures.

2. The antenna device according to claim 1,
wherein the orthomode transducer is configured to couple a first feed structure of the at least two feed structures with a first mode of the quad-ridged waveguide comprising a first orientation; and
wherein the orthomode transducer is configured to couple a second feed structure of the at least two feed structures to a second mode of the quad-ridged waveguide comprising a second orientation.

3. The antenna device according to claim 1,
wherein the orthomode transducer comprises a plurality of lateral ports,
wherein at least two of the lateral ports of the orthomode transducer are arranged in a same plane.

4. The antenna device according to claim 1,
wherein the antenna device forms a dual polarization single aperture antenna.

5. The antenna device according to claim 1,
wherein at least one of the at least two feed structures comprises a double-ridged waveguide.

6. The antenna device according to claim 1, further comprising:
a plurality of blind-mating waveguide connections;
wherein the at least two feed structures are waveguide structures; and
wherein the at least two feed structures extend between the orthomode transducer and respective ones of the blind-mating waveguide connections.

7. The antenna device according to claim 1, further comprising:
a layered structure,
a first external connection, and
a second external connection;
wherein the orthomode transducer comprises a plurality of lateral ports;
wherein the orthomode transducer comprises an axial port;
wherein the layered structure comprises:
a first layer,
a second layer, and
a third layer;
wherein the first layer comprises the quad-ridged waveguide, and
wherein the first layer comprises, on an inner surface, a first portion of waveguide structures that extend between the lateral ports of the orthomode transducer and a T-type waveguide joint;
wherein the second layer comprises, on a first side, a second portion of the waveguide structures that extend between the lateral ports of the orthomode transducer and the T-type waveguide joint, and
wherein the second layer comprises, on a second side, a first portion of a waveguide structure that extends from the T-type waveguide joint to the first external connection and a first portion of a waveguide structure that extends from the axial port of the orthomode transducer to the second external connection; and
wherein the third layer comprises a second portion of the waveguide structure that extends from the T-type waveguide joint to the first external connection, and
wherein the third layer comprises a second portion of the waveguide structure that extends from the axial port of the orthomode transducer to the second external connection.

8. The antenna device according to claim 1, further comprising:
a first double-ridged waveguide,
a second double-ridged waveguide, and
a third double-ridged waveguide;
wherein the orthomode transducer comprises a first lateral port, a second lateral port and an axial port;
wherein the first lateral port of the orthomode transducer comprises a transition between the quad-ridged waveguide and the first double-ridged waveguide,
wherein a first ridge of the quad-ridged waveguide transitions into a first ridge of the first double-ridged waveguide;
wherein the second lateral port of the orthomode transducer comprises a transition between the quad-ridged waveguide and the second double-ridged waveguide,
wherein a second ridge of the quad-ridged waveguide transitions into a first ridge of the second double-ridged waveguide;
wherein the axial port of the orthomode transducer comprises a transition between the quad-ridged waveguide and the third double-ridged waveguide,
wherein a third ridge of the quad-ridged waveguide transitions into a first ridge of the third double-ridged waveguide, and
wherein a fourth ridge of the quad-ridged waveguide transitions into a second ridge of the third double-ridged waveguide.

9. The antenna device according to claim 8, further comprising:
a combiner/splitter structure, and
a waveguide structure;
wherein the waveguide structure is configured to connect the first lateral port of the orthomode transducer and the second lateral port of the orthomode transducer with the combiner/splitter structure.

10. The antenna device according to claim 8,
wherein the antenna device is implemented in an antenna housing;
wherein the antenna housing comprises a first housing portion and a second housing portion,
wherein the quad-ridged waveguide is milled and/or micromachined in the first housing portion,
wherein the first double-ridged waveguide and the second double-ridged waveguide are, at least partially, milled and/or micromachined in the second housing portion, or
wherein the first double-ridged waveguide and the second double-ridged waveguide are milled and/or micromachined at a transition between the first housing portion and the second housing portion;
wherein the third double-ridged waveguide is milled and/or micromachined in the second housing portion; and
wherein an inner surface of the first housing portion forms a part of the first and second double-ridged waveguides.

11. The antenna device according to claim 10, wherein ridges of the third double-ridged waveguide are connected to a pair of ridges of the quad-ridged waveguide via a ridge step.

12. The antenna device according to claim 8,
wherein the antenna device is implemented in an antenna housing;
wherein the antenna housing comprises a first housing portion, a second housing portion and a third housing portion;
wherein the quad-ridged waveguide is milled and/or micromachined in the first housing portion;
wherein the first double-ridged waveguide and the second double-ridged waveguide are, at least partially, milled and/or micromachined in the second housing portion, or
wherein the first double-ridged waveguide and the second double-ridged waveguide are milled and/or micromachined at a transition between the first housing portion and the second housing portion;
wherein the third double-ridged waveguide is milled and/or micromachined in the second housing portion; and
wherein a combiner/splitter structure is milled and/or micromachined in the second housing portion;
wherein the second housing portion forms a part of the first and second double-ridged waveguides.

13. The antenna device according to claim 8,
wherein the first lateral port and the second lateral port are electromagnetically isolated from the axial port.

14. The antenna device according to claim 1,
wherein the quad-ridged waveguide extends perpendicular to the radiating aperture;
wherein ridges of the quad-ridged waveguide extend up to the radiating aperture; and
wherein the quad-ridged waveguide comprises a constant cross-section along its longitudinal extension.

15. The antenna device according to claim 1, further comprising:
an electromagnetically permeable cover;
wherein the electromagnetically permeable cover covers at least a part of the antenna device and/or wherein the electromagnetically permeable cover covers at least a part of the quad-ridged waveguide.

16. The antenna device according to claim 15,
wherein the electromagnetically permeable cover is configured to push a device under test into a device under test location while allowing for a transit of electromagnetic radiation from the quad-ridged waveguide to the device under test or vice versa.

17. An automated test equipment for testing a device under test, the automated test equipment comprising:
a device under test socket, and
the antenna device according to claim 1;
wherein the antenna device is arranged to test a device under test placed in the device under test socket.

18. An automated test equipment for testing a device under test, the automated test equipment comprising:
a device under test socket, and
one or more high frequency connectors;
wherein the one or more high frequency connectors are arranged beside the device under test socket.

19. The automated test equipment according to claim 18,
wherein the one or more high frequency connectors are blind mating waveguide connectors comprising double-ridged waveguides.

20. The automated test equipment according to claim 18, further comprising:
the antenna device according to claim 1;
wherein the antenna device comprises one or more external connections;
wherein the antenna device comprises an electromagnetically permeable cover, which covers at least a part of the antenna device and/or which covers at least a part of the quad-ridged waveguide;
wherein the device under test socket and the one or more high frequency connectors are arranged
such that the one or more external connections of the antenna device mate with the one or more high frequency connectors, and
such that the electromagnetically permeable cover of the antenna device pushes the device under test into the device under test socket when the one or more external connections of the antenna device mate with the one or more high frequency connectors;
wherein the electromagnetically permeable cover of the antenna device is formed from a low dielectric constant material.
